(19) United States
(12) Patent Application Publication
(10) Pub. No.: US 2026/0280283 A1
(43) Pub. Date: Sep. 17, 2026

(54) SYSTEM AND METHOD FOR PRIORITISING MAINTENANCE ACTIONS IN ELECTRIC POWER GRIDS

(71) Applicant: Safegrid Oy, Espoo (FI)

(72) Inventors: Lauri Kovanen, Espoo (FI); Brady Anderson, Espoo (FI); Juuso Parkkinen, Espoo (FI); Tomi Mickelsson, Espoo (FI); Tapio Mäntysalo, Espoo (FI); Juho Musakka, Espoo (FI); Juha Korhonen, Espoo (FI); Trung Trinh, Espoo (FI); Jan Kurzidim, Espoo (FI); Tatu Salminen, Espoo (FI); James Hobbs, Espoo (FI); Paula Laine, Espoo (FI); Klaus Ola, Espoo (FI); Jussi Hakunti, Espoo (FI)

(73) Assignee: Safegrid Oy, Espoo (FI)

(21) Appl. No.: 19/649,731

(22) Filed: Apr. 16, 2026

Related U.S. Application Data
(63) Continuation-in-part of application No. PCT/EP2025/055163, filed on Feb. 26, 2025.

(30) Foreign Application Priority Data
Feb. 26, 2024 (FI) 20245239

(51) Int. Cl. H02J 3/0012; G01R 31/11; H02J 3/00; H02J 3/001; H02J 13/10; H02J 13/12; H02J 103/35

(52) U.S. Cl. CPC H02J 3/0012; G01R 31/11; H02J 3/00125; H02J 3/003; H02J 13/10; H02J 13/12; H02J 2103/35

(57) ABSTRACT

Disclosed is a computer-implemented method and a system for prioritizing maintenance actions in an electric power grid. The method includes receiving precursor event data associated with a plurality of locations in the electric power grid; computing, for each location, a plurality of independent priority dimensions comprising a confidence metric computed based on signal quality and statistical distribution characteristics, an urgency metric computed based on a rate of change of an event frequency and an energy trajectory, and an impact metric determined based on a topology of the electric power grid and an estimated loss of electrical load; combining the confidence metric, the urgency metric, and the impact metric to generate a composite priority score; and generating a ranked list of the plurality of locations based on the composite priority score.

### CROSS-REFERENCE TO RELATED APPLICATIONS

This application is a continuation-in-part of International Application No. PCT/EP2025/055163, filed on Feb. 26, 2025, and which claims priority to Finnish Patent Application No. 20245239, filed on Feb. 26, 2024. The entire contents of each of the foregoing applications are incorporated herein by reference.

### TECHNICAL FIELD

The present disclosure relates to management and monitoring of electric grids for fault prevention. Moreover, the present disclosure relates to methods and systems for detection and prediction of faults in various components of an electric grid. Furthermore, the present disclosure relates to computer-implemented methods for prioritizing maintenance actions in an electric power grid based on precursor event data. Furthermore, the present disclosure relates to systems for prioritizing maintenance actions in an electric power grid based on precursor event data.

### BACKGROUND

An electric grid is an interconnected network that facilitates generation, transmission, and distribution of electricity. The electric grid may include a generator network, a transmission network, and a distribution network. The generator network may produce electricity using various sources such as fossil fuels, nuclear fuels, or renewable sources. The transmission network may carry high-voltage electricity, generated by the generator network, over long distances. The distribution network ensures a reliable and continuous supply of electricity to end-users. Each of the generator network, the transmission network, and the distribution network includes multiple components, such as substations, transmission and distribution lines, transformers, switchgears, and so on. For ensuring that the electric grid is functioning or operating in a stable or predictable manner, efficient, and safe, it may be necessary to monitor the components of the electric grid and ensure that the components are free from faults.

Faults in the components of the electric grid may occur due to a variety of circumstances such as weather conditions (lightning strikes or winds) or failure of equipment (due to malfunction, damage, overload, aging, manufacturing faults or vandalism). The faults may result in abnormal operation of the networks of the electric grid, or disruptions in transmission of electricity between the networks or delivery of electricity between the networks and/or end-users; thereby affecting reliability of the electric grid, the integrity of the grid infrastructure, and even public safety. While monitoring the electric grid, it is necessary to detect and locate events which are precursors or indicators of potential faults, in order to initiate actions to prevent an actual fault occurring. A plurality of events on a grid can be detected by sensitive sensors at any time span, and some of these events are indicative of abnormal or undesired situations or disturbances which are likely to impact the stability of the electric grid. There are specialized equipment, detectors, and monitoring systems that enable detection and monitoring of events.

Identification of the events and prompt relevant rectification may prevent occurrences of faults affecting the reliability of the power supply, the integrity of the grid infrastructure, and even public safety. This may allow minimizing potential losses which are likely to be incurred due to disruptions, triggered by the events and/or faults, of the electric grid. However, an accurate identification of components of the electric grid that may be causing events/faults, or prediction of the events/faults, may be challenging and require a sophisticated analysis. This is true especially for electric grids with numerous interconnected systems and components, when events to be detected are sporadic/intermittent, or when the signals detected are weak or buried under unharmful noise. False detections of events or false identification of components causing the events, i.e., false alarms are required to be avoided in order to save the maintenance crew resources and total cost of grid operations and maintenance. In large electric grids, analysis, and management of data, which may be collected by fault detection/monitoring equipment (such as sensors and monitoring devices), in real-time may increase the requirement of financial, human, and software resources. The collection of data is challenging, and accuracy of the collected data may be questionable in harsh weather conditions (such as floods, lightning, storms, cyclones) and in event of natural disasters (such as earthquakes) or when the sensors are detecting irrelevant noise. This is because, weather and event may damage, or cause malfunctioning of, the sensors and/or monitoring equipment and hinder the ability to collect accurate data.

Monitoring systems deployed in electric power grids are configured to detect and report precursor events, such as partial discharge events and high-impedance fault events, using a plurality of sensors. However, utilities and network operators that deploy such sensing infrastructure often face a problem of overwhelming volumes of detected precursor event signals that are difficult to act upon. When monitoring systems detect and report every precursor event without discrimination, the result is a continuous stream of alarms. Operators may become desensitized to alerts because a majority of the alarms do not correspond to imminent faults and instead may indicate benign background noise, anomalous transient events, or low-level activity from components that have been stable for extended periods. This phenomenon, referred to as alarm fatigue, is a significant barrier to effective use of monitoring systems, and genuine warning signals may go unheeded in the noise.

However, existing monitoring systems suffer from certain limitations. These systems lack a mechanism to differentiate a reliability of the precursor event data from a temporal development of the precursor event activity and from a consequence of a fault at a given location based on a topology of the electric power grid. Conventional systems do not compute independent priority dimensions to rank detected precursor events according to their urgency and potential consequence. Further, operators using conventional systems must manually interpret complex datasets and manually determine which events require immediate action, which events require monitoring, and which events can be disregarded. Furthermore, undifferentiated alert systems generate maintenance callouts that consume maintenance budget without proportionate benefit because alerts lack context about severity, urgency, or network-level impact. As a result, existing systems provide visibility of precursor event data but do not provide automated decision support for prioritizing maintenance actions.

Existing systems for monitoring precursor events in electric power grids are further limited in that conventional systems generally do not incorporate sufficient contextual information to distinguish between a location that is electrically important and a location that is operationally significant to society or to an operator of the electric power grid. In practice, the consequence of a fault at a given location is not determined solely by electrical load magnitude. The consequence may depend on whether an affected location supplies a critical infrastructure, such as hospitals, airports, industrial plants, data centers, communication hubs, military facilities, or other strategically significant consumers. Conventional monitoring systems may provide event locations and alarm indications, but do not adequately incorporate external geographic information, map-based analysis, electrical distance, or proximity to the critical infrastructure into a location-specific consequence assessment. Furthermore, conventional systems generally do not take into account whether a consumer or load is capable of islanded operation, self-supply, or temporary autonomous service using local generation or storage. As a result, conventional systems may overestimate importance of some locations while underestimating importance of other locations.

Existing systems are also limited in that such systems typically do not distinguish sufficiently between different physical causes of precursor event activity. In practical electric power grids, precursor events may originate from a range of developing faults and degradation mechanisms, including partial discharge, insulation degradation, contact degradation, bad joints, poor terminations, conductor fatigue, broken strands, vegetation animal interaction, arcing phenomena, contamination, grounding defects, switching anomalies, and environmental stress effects. Some of these causes may develop gradually over extended periods, while other causes may present as intermittent or condition-dependent faults. Conventional systems that detect precursor events without classifying likely fault causes do not provide operators with information regarding whether an observed pattern is likely associated with insulation breakdown, vegetation contact, animal interference, bad connections, or another failure mechanism. Consequently, maintenance responses may be delayed, misdirected, or selected without adequate understanding of a likely fault source.

Further, many conventional systems do not sufficiently account for a fact that some signals detected in electric power grids resemble precursor events even though such signals are generated by healthy equipment or benign operating conditions. Modern electric power grids increasingly include semiconductor-based devices and other power-electronic equipment, including inverters, converters, switch-mode power supplies, electric vehicle charging stations, battery energy storage systems, generators, and battery chargers. Such equipment can generate repetitive or structured signal patterns that may superficially resemble precursor event activity. Conventional systems that lack mechanisms for recognizing healthy disturbance-source signatures may assign unwarranted significance to such signals, thereby increasing a number of false positives. Similarly, conventional systems generally do not provide adequate means for incorporating operator validation or invalidation of event locations into subsequent reliability assessments. When operators determine from field knowledge or interface review that a detected event location is incorrect or non-actionable, conventional systems typically do not feed such information back into confidence evaluation or model learning. As a result, reliability assessment remains static and does not improve through user interaction or accumulated field experience.

Another limitation of conventional systems lies in a treatment of fault progression by conventional systems. Existing systems may provide indications of increasing event counts or increasing signal magnitude, but do not adequately separate different aspects of developing risk. In many cases, a practical maintenance significance of a developing fault depends not only on whether precursor event activity is increasing, but also on how severely a component is already damaged, how close the component is to failure, and how accurately a location of the precursor event activity is known. Conventional systems generally do not distinguish a current damage state from a rate of change of the current damage state, and therefore do not provide a structured differentiation between severity and urgency. Similarly, conventional systems often present a single location estimate without expressing whether the estimated location is tightly clustered, broadly distributed, or intrinsically uncertain due to sampling-rate limitations, low signal energy, or inconsistent detections. A lack of explicit treatment of severity and location accuracy reduces usefulness of maintenance prioritization, because operators may not know whether a high-priority location is already badly damaged, merely changing rapidly, or simply poorly localized.

Existing systems are further limited in an ability to aggregate large numbers of detected signal locations into coherent observations that correspond to developing fault phenomena. In practice, precursor event detections may appear as groups of signal locations distributed over time and space, and such groups may need to be clustered, merged, or interpreted jointly. Conventional monitoring systems frequently present raw detections individually, or with only rudimentary grouping, without using graph-based aggregation, density-based clustering, weighting by signal properties, or comparison of recurring patterns such as phase-resolved activity or time-of-day behavior. Without aggregation of the raw detections into meaningful observations, operators may be presented with many separate detections that are in fact manifestations of the same developing defect, or with merged event groupings that incorrectly conflate unrelated phenomena. Such limitations impair both visual interpretation and automated prioritization.

Conventional systems also lack adequate integration between event prioritization and downstream maintenance workflow. Even where alarms or rankings are provided, conventional systems often stop at alert presentation and do not support a closed operational loop in which prioritized locations are converted into work orders, maintenance crews execute repairs, repair reports are returned to the system, and the returned repair information is used to improve subsequent prioritization and prediction. In practice, field repair outcomes contain useful information regarding whether a predicted fault source was correct, whether a detected location corresponded to an actual defect, what type of damage was observed, and whether the maintenance action resolved the precursor event activity. Conventional systems that do not ingest and learn from such repair reports fail to exploit a source of supervision and validation. This weakens long-term performance and prevents systematic refinement of confidence estimation, urgency modelling, consequence assessment, and fault-type classification.

Another limitation of conventional systems is that recalculation of event priority is often either too infrequent or too rigid. In practice, an appropriate frequency for recomputing maintenance priorities may depend on changing weather conditions, forecasted environmental stress, crew availability, a present activity level of a signal source, or an observed rate of change of precursor event behavior. Existing systems generally do not allow a recalculation frequency to be configured by the operator or adjusted automatically according to operational context. Consequently, some systems may recalculate too slowly during rapidly developing situations, while other systems may waste computational and operator resources by recalculating too frequently during stable periods. An absence of adaptive recalculation frequency limits practical scalability and weakens usefulness of prioritization outputs under changing field conditions.

Conventional systems are also limited in a use of modelling techniques by conventional systems for temporal development and future fault prediction. While some systems may identify current event levels, such systems often do not employ a sufficiently broad range of modelling approaches for predicting how a component will continue to degrade, when failure may occur, or where new faults may emerge. In practical grid operation, future fault occurrence may depend on a combination of past precursor event activity, component age, component type, grid topology, weather forecast, surrounding infrastructure, and a presence of known environmental or operational stressors. Existing systems generally do not combine such factors into models that predict not only whether a presently observed defect will worsen, but also when and where new faults may appear elsewhere in the electric power grid. Similarly, conventional systems may not adequately exploit relationships between partial discharge activity and other steady-state electrical quantities, such as load-dependent signal strength, to predict future precursor event behavior under forecast operating conditions.

A further limitation arises in operator presentation and interface functionality. Existing monitoring systems may provide maps, lists, or alarms, but often do not provide sufficiently rich interface views for understanding significance of precursor event activity at a location. Operators may need to inspect not only a ranked list, but also heatmaps, time-based plots, time-of-day distributions, signal energy plots, issue indicators, spatial relationships between detections, and phase-resolved partial discharge plots in one or more graphical forms. Conventional systems frequently lack mechanisms for presenting hidden low-confidence locations by default, filtering views by area, issue type, time range, or signal energy, or allowing user customization of parameters associated with the topology of the electric power grid. Conventional systems also often lack interfaces that capture operator feedback as structured validation data. An absence of such functions increases cognitive burden and limits an ability of operators to convert prioritized event data into informed field decisions.

In addition, conventional systems generally do not incorporate economic optimization into maintenance prioritization in a sufficiently explicit manner. In practical operation, maintenance resources are finite, and an operator must determine not merely which locations appear most significant electrically, but how to allocate crews, time, and budget most effectively. This includes determining whether a location should be repaired, replaced, washed, inspected, or simply monitored, and determining an appropriate time window for each such action. Existing systems typically do not provide timing recommendations for different maintenance actions based on combined assessments of confidence, urgency, impact, and resource availability. Nor do existing systems adequately support optimization of maintenance scheduling to minimize expected cost, expected outage consequence, or broader operational risk across the electric power grid.

Therefore, in light of the foregoing discussion, there exists a need for a computer-implemented method and a system that can convert large volumes of detected precursor event data in an electric power grid into an automatically generated prioritization of locations requiring maintenance actions.

### SUMMARY

The aim of the present disclosure is to provide a computer-implemented method and a system to prioritize maintenance actions in an electric power grid based on detected precursor event data. The aim of the present disclosure is achieved by a computer-implemented method and a system for prioritizing maintenance actions in an electric power grid as defined in the appended independent claims to which reference is made to. The aim of the present disclosure is further achieved by a computer-implemented method for prioritizing maintenance actions in an electric power grid, wherein one or more precursor events are detected using a plurality of sensors to generate the precursor event data, and wherein a location for each precursor event of the one or more precursor events is determined using a travelling-wave method based on differences in arrival times of travelling waves received at the plurality of sensors, as defined in an appended further independent claim to which reference is made to. Advantageous features are set out in the appended dependent claims.

Throughout the description and claims of this specification, the words “comprise”, “include”, “have”, and “contain” and variations of these words, for example “comprising” and “comprises”, mean “including but not limited to”, and do not exclude other components, items, integers, or steps not explicitly disclosed also to be present. Moreover, the singular encompasses the plural unless the context otherwise requires. In particular where the indefinite article is used, the specification is to be understood as contemplating plurality as well as singularity, unless the context requires otherwise.

### “Grid Fault” or “a Fault”

A grid fault is an abnormal condition in the power system that disrupts the regular flow of electrical current. This can be caused by various issues such as short circuits (where there's an unintended connection between two points at different voltages), open circuits (where the electrical path is broken), or equipment failures. Grid faults can result in power outages, equipment damage, and safety hazards. They require immediate attention to identify, isolate, and rectify to restore normal operations and ensure the safety of the public and utility workers.

Grid “events” include but are not limited to
Electrical deviations: Such as voltage spikes or dips, frequency variations, harmonic distortions, unexpected power flows, and partial discharge events. These are typically detected by electrical sensors measuring the grid's electrical characteristics.
High-frequency signals: Emitted by phenomena like partial discharges, which indicate insulation issues or other faults in high-voltage equipment. High-frequency sensors are required to detect these subtle yet critical signals.
Acoustical signals: Unusual sounds or vibrations, which can indicate mechanical issues in transformers, switchgear, or other components. Acoustic sensors can capture these signals, allowing for early detection of mechanical failures or malfunctions.
Mechanical changes: Such as temperature variations, abnormal vibrations, or structural stresses, which might signal equipment degradation, overheating, or physical damage. These are detected by various sensors, including temperature, vibration, and strain gauges.

### “Precursor Event”

A precursor event is an incident or condition that occurs before a more significant event, serving as a warning sign or indicator that the significant event may happen. Precursor events are observed occurrences that directly correlate with the likelihood of a future event, allowing stakeholders to take preventative measures. In the context of a power grid, for example, a precursor event could be an unusual vibration in a transformer, indicating that it might fail soon if no action is taken.

### “Predictive Event”

A predictive event, on the other hand, is identified through the analysis of data and predictive modeling, indicating that a specific event is likely to occur in the future based on current trends, patterns, or conditions. Unlike precursor events, which are actual observed incidents, predictive events are often forecasted through statistical analysis, machine learning models, or other predictive analytics techniques. For instance, a predictive model might forecast a peak demand period on the power grid, suggesting potential overload conditions before they occur.

### “Signal Strength”

The strength of a signal, signal strength, is a generalization that covers any combination of event count in a timespan, signal amplitude, signal repetition rate, voltage, current, magnetic or electrical field strength, power, or energy levels of the high frequency signals, and wherein reduction in the signal strength of the signals correspond to reduction of the phenomena and increase in the signal strength of the signals correspond to an increasing phenomena.

### BRIEF DESCRIPTION OF THE DRAWINGS

FIG. 1 illustrates an exemplary visual alert that corresponds to prediction of faults in an electric grid, in accordance with an embodiment of the present disclosure;

FIG. 2 illustrates an exemplary visual alert that corresponds to prediction of faults in an electric grid, according to an embodiment of the present disclosure;

FIG. 3A illustrates a flowchart for prioritizing tasks for fixing issues in an electric grid, according to an embodiment of the present disclosure;

FIG. 3B illustrates another flowchart for prioritizing tasks for fixing issues in an electric grid, in accordance with an embodiment of the present disclosure;

FIG. 3C illustrates a flowchart for a probability model for a precursor event to occur at a location in an electric grid, in accordance with an embodiment of the present disclosure;

FIG. 3D illustrates a flowchart for a list of prioritized tasks with a proposed time to dispatch the crew to the event location, in accordance with an embodiment of the present disclosure;

FIG. 4 illustrates an exemplary visual alert that corresponds to prediction of faults in an electric grid, according to an embodiment of the present disclosure;

FIG. 5 illustrates an exemplary visual alert that corresponds to prediction of faults in an electric grid, according to an embodiment of the present disclosure;

FIG. 6 illustrates an exemplary visual alert that corresponds to prediction of faults in an electric grid, according to an embodiment of the present disclosure;

FIG. 7 illustrates an exemplary visual alert that corresponds to prediction of faults in an electric grid, according to an embodiment of the present disclosure;

FIG. 8 shows a schematic diagram of a system for predicting faults in electric grids, in accordance with an embodiment of the present disclosure; and

FIG. 9 illustrates steps of a method for detecting one or more events, determining one or more locations, and generating alerts that include one or more events, one or more locations, and one or more components of the electric grid, in accordance with an embodiment of the present disclosure;

FIG. 10 shows a phase resolved partial discharge view, in accordance with an embodiment of the present disclosure;

FIG. 11 shows oscillographs of the high frequency and phase signals, in accordance with an embodiment of the present disclosure;

FIG. 12 shows a schematic block diagram of a system for prioritizing maintenance actions in an electric power grid, in accordance with a further embodiment of the present disclosure;

FIG. 13 shows a flowchart of a computer-implemented method for prioritizing maintenance actions in an electric power grid, in accordance with a further embodiment of the present disclosure;

FIG. 14 shows a detailed flowchart of a method including detection, travelling-wave localization, and dynamic updating for prioritizing maintenance actions in an electric power grid, in accordance with a further embodiment of the present disclosure;

FIG. 15 shows a block diagram illustrating an architecture of a prioritization engine for computing priority dimensions and generating a composite priority score, in accordance with a further embodiment of the present disclosure;

FIG. 16 shows a map view of a user interface rendering a ranked list of a plurality of locations on a topology map of the electric power grid, in accordance with a further embodiment of the present disclosure;

FIG. 17 shows an event view of the user interface illustrating an event cluster on a single feeder with visual representations of a confidence metric, an urgency metric, and an impact metric, in accordance with a further embodiment of the present disclosure; and

FIG. 18 shows an event detail view of the user interface illustrating correlation of an event cluster with a forecast of ambient conditions, in accordance with a further embodiment of the present disclosure.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

In a first aspect, the present disclosure provides a computer-implemented method for prioritizing maintenance actions in an electric power grid, the method comprising:
receiving precursor event data associated with a plurality of locations in the electric power grid;
computing, for each location of the plurality of locations, a plurality of independent priority dimensions based on the precursor event data, the plurality of independent priority dimensions comprising:
   (a) a confidence metric indicative of a reliability of the precursor event data at the location, wherein the confidence metric is computed based on signal quality and statistical distribution characteristics of the precursor event data;
   (b) an urgency metric indicative of a temporal development of precursor event activity at the location, wherein the urgency metric is computed based on a rate of change of an event frequency of the precursor event activity and an energy trajectory of the precursor event activity; and
   (c) an impact metric indicative of a consequence of a fault at the location, wherein the impact metric is determined based on a topology of the electric power grid and an estimated loss of electrical load associated with the location;
combining the confidence metric, the urgency metric, and the impact metric to generate a composite priority score for each location of the plurality of locations; and
generating a ranked list of the plurality of locations based on the composite priority score for prioritizing the maintenance actions in the electric power grid.

The present method provides automated prioritization of maintenance actions in the electric power grid. The method achieves this through a synergistic interaction between the plurality of independent priority dimensions, in which the confidence metric differentiates reliable precursor event data from unreliable precursor event data, the urgency metric captures temporal development of the precursor event activity to identify accelerating deterioration, and the impact metric incorporates system-level consequence modelling based on the topology of the electric power grid and the estimated loss of electrical load. These three independently computed metrics are then combined into the composite priority score, which enables automated ranking of the plurality of locations. The ranked list generated from the composite priority score provides an actionable output that directs maintenance resources toward locations where a combination of signal reliability, temporal deterioration behavior, and network-level consequence is highest. This integrated approach shifts grid monitoring from detection and display of precursor events to automated interpretation and decision support, enabling operators to act on prioritized information rather than manually interpreting large volumes of undifferentiated precursor event data.

In a second aspect, the present disclosure provides a system for prioritizing maintenance actions in an electric power grid, the system comprising:
one or more processors; and
a memory storing instructions that, when executed by the one or more processors, cause the system to:
   receive precursor event data associated with a plurality of locations in the electric power grid;
   compute, for each location of the plurality of locations, a plurality of independent priority dimensions based on the precursor event data, the plurality of independent priority dimensions comprising:
      (a) a confidence metric indicative of a reliability of the precursor event data at the location, wherein the confidence metric is computed based on signal quality and statistical distribution characteristics of the precursor event data;
      (b) an urgency metric indicative of a temporal development of precursor event activity at the location, wherein the urgency metric is computed based on a rate of change of an event frequency of the precursor event activity and an energy trajectory of the precursor event activity; and
      (c) an impact metric indicative of a consequence of a fault at the location, wherein the impact metric is determined based on a topology of the electric power grid and an estimated loss of electrical load associated with the location;
   combine the confidence metric, the urgency metric, and the impact metric to generate a composite priority score for each location of the plurality of locations; and
   generate a ranked list of the plurality of locations based on the composite priority score for prioritizing the maintenance actions in the electric power grid.

The present system provides a hardware and software architecture for automated prioritization of maintenance actions in the electric power grid. The one or more processors execute instructions stored in the memory to perform computation of the plurality of independent priority dimensions and generation of the composite priority score. The system receives precursor event data from the electric power grid and processes the precursor event data through the confidence metric computation, the urgency metric computation, and the impact metric computation to produce independently calculated values for each location of the plurality of locations. The system then combines these independently calculated values to generate the composite priority score, which drives the ranked list of the plurality of locations. The architecture of the system enables continuous processing of new precursor event data to maintain an up-to-date ranked list that reflects a current condition of the electric power grid. The system thereby provides automated decision support for directing maintenance actions to locations where the combination of reliability of the precursor event data, temporal development of the precursor event activity, and consequence of a fault is highest.

In a third aspect, the present disclosure provides a computer-implemented method for prioritizing maintenance actions in an electric power grid, the method comprising:
detecting one or more precursor events using a plurality of sensors to generate precursor event data;
determining, for each precursor event of the one or more precursor events, a location using a travelling-wave method based on differences in arrival times of travelling waves received at the plurality of sensors, such that the precursor event data is associated with a plurality of locations in the electric power grid;
computing, for each location of the plurality of locations, a plurality of independent priority dimensions based on the precursor event data, the plurality of independent priority dimensions comprising:
   (a) a confidence metric indicative of a reliability of the precursor event data at the location, wherein the confidence metric is computed based on signal quality and statistical distribution characteristics of the precursor event data;
   (b) an urgency metric indicative of a temporal development of precursor event activity at the location, wherein the urgency metric is computed based on a rate of change of an event frequency of the precursor event activity and an energy trajectory of the precursor event activity; and
   (c) an impact metric indicative of a consequence of a fault at the location, wherein the impact metric is determined based on a topology of the electric power grid and an estimated loss of electrical load associated with the location;
combining the confidence metric, the urgency metric, and the impact metric to generate a composite priority score for each location of the plurality of locations; and
generating a ranked list of the plurality of locations based on the composite priority score for prioritizing the maintenance actions in the electric power grid.

The method according to the third aspect provides automated prioritization of maintenance actions in the electric power grid in which the generation of the precursor event data and the association of the precursor event data with the plurality of locations are explicitly performed through detection of the one or more precursor events using the plurality of sensors and through determination of the location for each precursor event using the travelling-wave method based on differences in arrival times of the travelling waves received at the plurality of sensors. This achieves the automated prioritization through a synergistic interaction between the detecting of the one or more precursor events, the determining of the location for each precursor event using the travelling-wave method, and the computation of the plurality of independent priority dimensions. The detecting of the one or more precursor events using the plurality of sensors acquires signal data associated with each precursor event that occurs in the electric power grid. The determining of the location for each precursor event using the travelling-wave method based on differences in arrival times of the travelling waves received at the plurality of sensors spatially associates each precursor event with a specific location in the electric power grid, such that the precursor event data becomes associated with the plurality of locations on a per-location basis rather than with general sensor coverage regions. Because the precursor event data is associated with the plurality of locations through the determined locations, the computation of the confidence metric, the urgency metric, and the impact metric is performed on a per-location basis using the precursor event data so generated, thereby providing a direct link between the detection step, the localization step, and the computation of the plurality of independent priority dimensions. The composite priority score generated by combining the confidence metric, the urgency metric, and the impact metric enables ranking of the plurality of locations for prioritizing the maintenance actions in the electric power grid with spatial specificity provided by the travelling-wave method.

In the context of the present disclosure, the term “electric power grid” refers to an interconnected network of electrical components configured to generate, transmit, and distribute electrical power. The electric power grid comprises a plurality of components including, but not limited to, conductors, cables, cable joints, cable terminations, overhead line segments, insulators, switchgear, transformers, surge voltage arrestors, and other electrical equipment. The electric power grid may operate at medium-voltage levels, high-voltage levels, or a combination thereof. The electric power grid has a topology that defines the physical and electrical connections between the plurality of components and that determines how electrical load flows from generation sources to end consumers. The topology of the electric power grid includes feeder configurations, branching structures, and interconnection points that affect the consequence of a fault at any given location.

Further, the term “precursor event” as used in the following passages refers to a detectable physical or electrical phenomenon that occurs prior to a catastrophic fault and that is indicative of deteriorating condition of a component of the electric power grid. A precursor event is characterized by a transient electrical signal that can be captured by sensors operating at high sampling rates. Precursor events include, but are not limited to, partial discharge events, high-impedance fault events, and other high-frequency anomalies that indicate degradation of insulation or other components. A partial discharge event is a localized electrical discharge that only partially bridges the insulation between conductors and that occurs within cracks, contaminants, or loose interfaces inside the insulation of a cable, a cable termination, an insulator of an overhead line, a surge voltage arrestor, loose contacts of joints, bad contacts of switchgear, or in insulation of switchgear, transformers, or galvanically connected sensor devices. A high-impedance fault event refers to a fault condition characterized by a relatively low fault current that may be caused by a conductor which has fallen from an insulator or support, a conductor touching a galvanically floating metal object, a contaminant on a non-insulating switchgear component at high electric field, corona in unexpected places, or broken or high-impedance grounding.

Further, the term “precursor event data” refers to data generated by detection and measurement of one or more precursor events in the electric power grid. The precursor event data includes information relating to characteristics of detected precursor events such as timing information, signal waveforms, amplitudes, energies, frequencies, and spatial locations. The precursor event data is associated with a plurality of locations in the electric power grid, wherein each location corresponds to a position in the electric power grid at which one or more precursor events have been detected. The precursor event data may be generated by a plurality of sensors distributed across the electric power grid and configured to detect high-frequency transient signals associated with precursor events.

Further, the term “plurality of independent priority dimensions” refers to a set of separately calculated metrics, each of which captures a distinct aspect of risk associated with a given location in the electric power grid. The plurality of independent priority dimensions comprises the confidence metric, the urgency metric, and the impact metric. Each of the plurality of independent priority dimensions is computed independently of the others based on different input parameters and different analytical methods. The independence of the plurality of priority dimensions ensures that each dimension contributes a distinct and non-redundant assessment to the composite priority score.

Further, the term “confidence metric” refers to a computed value that quantifies a reliability of the precursor event data at a given location. The confidence metric is indicative of a degree to which the precursor event data at the location represents genuine precursor event activity as opposed to noise, interference, or spurious signals. The confidence metric is computed based on signal quality and statistical distribution characteristics of the precursor event data. Signal quality includes, but is not limited to, a signal-to-noise ratio of the detected precursor events. Statistical distribution characteristics include, but are not limited to, patterns of discharge activity that are characteristic of genuine localized insulation defects as opposed to random, non-localized distributions that are characteristic of background noise and interference. The confidence metric further incorporates assessment of sensor agreement and localization consistency, wherein agreement among multiple sensors increases the confidence metric. The confidence metric implements noise discrimination to suppress non-physical or spurious signals from the precursor event data.

Further, the term “urgency metric” refers to a computed value that quantifies a temporal development of precursor event activity at a given location. The urgency metric is indicative of how rapidly the precursor event activity at the location is developing. The urgency metric is computed based on a rate of change of an event frequency of the precursor event activity and an energy trajectory of the precursor event activity. The rate of change of the event frequency captures whether the frequency of precursor events at the location is increasing, decreasing, or remaining stable over time. A location experiencing a sudden increase in the event frequency is assigned a higher urgency metric than a location with a similar absolute level of the event frequency that has been stable over an extended period. The energy trajectory captures an evolution of signal amplitude, energy, or power of the precursor event activity over time. Increasing discharge energy, particularly when combined with increasing event frequency, is indicative of accelerating deterioration at the location. The urgency metric applies time-series analysis and recency-weighted models, such as moving average models, to reflect recent history of the precursor event activity without being dominated by transient spikes or long-past episodes. This recency-weighted approach captures a current risk trajectory at the location rather than a simple cumulative count.

Further, the term “impact metric” refers to a computed value that quantifies a consequence of a fault at a given location in the electric power grid. The impact metric is indicative of a severity of disruption that would occur if a component at the location were to fail. The impact metric is determined based on a topology of the electric power grid and an estimated loss of electrical load associated with the location. The topology of the electric power grid is used to determine which downstream load branches are connected through the affected location. The estimated loss of electrical load is computed based on the downstream power consumption of all load branches connected through the location. A failure at a high-load, low-redundancy location carries a higher impact metric than a failure at a peripheral location with minimal connected load. The impact metric integrates system-level dependency modelling, including assessment of network redundancy and network criticality, into the prioritization of maintenance actions.

Further, the term “composite priority score” refers to a computed value generated by combining the confidence metric, the urgency metric, and the impact metric for a given location. The composite priority score represents a unified assessment of priority for the given location. Methods for combining the confidence metric, the urgency metric, and the impact metric include, but are not limited to, weighted aggregation, rule-based logic, statistical models, and machine learning models. In weighted aggregation, each of the confidence metric, the urgency metric, and the impact metric is multiplied by a respective weight, and the weighted values are summed to produce the composite priority score. In rule-based logic, predefined rules are applied to the values of the confidence metric, the urgency metric, and the impact metric to determine the composite priority score. In statistical or machine learning models, a model trained on historical data is applied to the confidence metric, the urgency metric, and the impact metric to generate the composite priority score.

Further, the term “ranked list” refers to an ordered sequence of the plurality of locations arranged according to the composite priority score. The ranked list assigns a relative position to each location of the plurality of locations, such that the location with the highest composite priority score is positioned at the top of the ranked list and the location with the lowest composite priority score is positioned at the bottom of the ranked list. The ranked list provides an actionable output that identifies which locations in the electric power grid require maintenance actions with the highest priority. The ranked list is configured to be rendered on a user interface for review by an operator or maintenance planner.

The identification and rectification of potential faults may allow avoiding potential downtime, which lead to significant financial costs. Furthermore, prediction of potential faults allows improving reliability, resilience, and flexibility of the electric grid. The users, i.e., the engineers and operators of the electric grid proactively correct emerging faults, thereby, extend service life of assets (i.e., components of the electric grid) while avoiding costly effects of unplanned outages. For example, Partial Discharge (PD) event detection may allow avoiding potential insulator degradation and potential electric grid overloads. Embodiments enable locating events and predicting faults for both overhead lines and underground cables. In general, faults in the electric grid are caused by equipment failures, which are preceded by transient patterns, such as PD or intermittent faults (IF). The predictive maintenance prevents fault occurrences.

The one or more events that are precursors of one or more faults in the electric grid, are detected based on parameters associated with the signals that are propagating through the distribution network or the transmission network of the electric grid. The faults may be incidents that have potential to cause damage to components of the electric grid, and cause harm to nature, property, or living beings. The components may include substations of the transmission/distribution network, transmission lines and cables of the transmission network, distribution lines and cables of the distribution network, transformers of the transmission/distribution network, switchgear/circuit breakers/protective equipment of the distribution network, and so on. The one or more events may be detected further based on radiation produced by operation of the components in the transmission/distribution network. The parameters associated with the signals, based on which the one or more events are detected, may include one or more of energy level, power level, voltage level, current level, electric field amplitude, magnetic field amplitude, frequency, and so on.

The signals may be processed to improve the signal-to-noise ratio and to isolate the event signatures from background noise. Techniques such as filtering, wavelet transforms, Fast Fourier Transform (FFT), and cepstrum analysis may be used to enhance the signals. Thereafter, key features of the signals may be extracted for analysis. These features may include amplitude, phase angle, frequency, signal shape, signal duration, rising/falling edge and so on. The amplitude feature includes peak value of the signals, which are indicative of severity of the event. The phase angle is used to identify a position of occurrence of the event within a cycle. The phase angle facilitates identifying a type of event and an origin (time-instance of inception) of the event. The frequency may indicate a type of fault as different types of a particular event have unique spectral signatures. The frequency spectrum of the event indicates a distribution of energy of the signal across different frequencies. The signal shape and duration may allow differentiating between various types of a particular event. In particular, signal features that are phase-synchronized to the mains frequency can be used in a form of phase-resolved charts, especially in partial discharge signals a phase-resolved partial discharge (PRPD) chart and electronic analysis of it, may be used.

In accordance with an embodiment, prior to the feature extraction, the signals may be preprocessed for identification of information associated with events and reduction of noise. The signals are preprocessed using techniques that may include wavelet transform, digital filtering, principal component analysis, and so on. Feature extraction allows identifying the most relevant features for classification of different events or types of each event, improving performance of a machine learning model that is used for classification, reducing computational complexity, and so on. The features may include statistical parameters (such as mean, standard deviation, skewness, kurtosis, and so on) of signal amplitude, energy distribution in frequency bands, time-frequency characteristics derived from signal processing, and so on.

Optionally, the method involves analyzing both historical and real-time data of detected events to identify patterns of recurring anomalies (i.e., referring to events or anomalies that happen repeatedly or consistently over time within the electric grid). This analysis is performed over predefined time intervals and across specific geographic regions within the electric grid. By identifying these patterns, the method facilitates proactive maintenance and improves fault prediction accuracy. Pattern detection may comprise analyzing temporal patterns of signal anomalies across predefined time intervals, examining frequency domain characteristics to identify fault-related harmonics, and evaluating spatial patterns of events across geographic regions to correlate anomalies with specific grid components. This comprehensive analysis enables more accurate identification of potential fault locations and better understanding of emerging issues within the electric grid.

Exemplary machine learning models used for the classification may include neural networks, Support Vector Machines (SVMs), Random Forests, k-Nearest Neighbors (k-NN), and so on. The neural networks model complex nonlinear relationships between features and event types, offering high accuracy in classification tasks. The SVMs are effective for high-dimensional data and find hyperplanes that best separate different event classes in the feature space. The random forests are an ensemble learning method that may use multiple decision trees to improve classification accuracy and may be robust against overfitting. The k-NN may classify samples based on the majority class among their k-nearest neighbors in the feature space.

The classification allows preemptive identification and repairing of faults or defects prior to the faults/defects leading to failure of components of the electric grid. For example, by classifying different types of a certain event, it may be possible to determine whether an issue in a component is due to aging, insulation, environmental factors, or mechanical defects, and apply appropriate remediation measures to overcome the issue. For example, an event such as partial discharge may be classified as corona discharge, surface partial discharge, floating partial discharge, internal partial discharge, void partial discharge, or a phase-synchronous sparking. One of the event types is lightning, which, when detected as hitting directly or at close proximity to an electrical grid, is a precursor event to broken insulation, transformers, AMR meters, and lightning arrestors. Lightning events can be located by integrating data from lightning data services, or detected as traveling waves on the grid lines, or geolocated by lightning sensors or traveling wave sensors on the grid.

The method involves analyzing patterns and temporal characteristics of detected phenomena to determine both fault severity and fault locations. By evaluating the timing, frequency, and duration of events, the method provides insights into the underlying nature and potential impact of faults. This analysis enables more accurate assessment of fault severity and identification of critical areas within the electric grid that require attention.

Optionally, the one or more components, where the one or more events are detected, may include one or more of substations in the transmission network, substations in the distribution network, transmission lines in the transmission network, distribution lines in the distribution network, equipment in the transmission network, or equipment in the distribution network. The transmission lines and the distribution lines may include one or more overhead lines built of bare conductors, covered conductors, insulated conductors, or coaxial cables, and underground cables, which can be for example oil-filled, XLPE (Cross-Linked Polyethylene) or GIL (Gas-Insulated Lines) cables, and busbars.

Optionally, the one or more events are detected using a set of sensors. The set of sensors may include one or more of each of a magnetic field detection sensor, an electric field detection sensor, an electromagnetic field detection sensor, an accelerometer, a temperature sensor, a wind detection sensor, a lightning sensor, a humidity sensor, a strain gauge sensor, a vibration sensor, an image sensor, a motion sensor, a personal device, an acoustic sensor, an ultrasound sensor, an infrared sensor, an ultraviolet sensor, or a traveling wave sensor, protection or switch device measurement or action data, load or generation connect/disconnect/start/stop data and so on. Each of the signals, which are propagating through the distribution network or the transmission network of the electric grid, may be associated with a first phase, a second phase, a third phase, a neutral conductor, or a ground conductor. Each sensor of the set of sensors may be configured to simultaneously monitor the signals associated with the first phase, the second phase, the third phase, the neutral conductor, or the ground conductor, for detecting the one or more events.

The set of sensors may measure the parameters from the signals and transmit the measurements and the signals to a server that includes a processor. The processor may be included in a server. The processor may be implemented as one of, but not limited to, a microprocessor, a microcontroller, or a controller. In an example, the processor may be implemented as an application-specific integrated circuit (ASIC) chip, or a reduced instruction set computer (RISC) chip. The processor may be operable to detect the one or more events based on the measurements and processing of the signals. The set of sensors may be configured to monitor changes in signal propagation and fault-related anomalies over time. By continuously measuring parameters such as amplitude, phase angle, and frequency, the sensors can identify trends or patterns that indicate the development of potential faults. This temporal analysis allows for early detection of issues before they escalate into major faults.

After the detection of the one or more events, the one or more locations, in the distribution network or the transmission network, where the one or more events are detected are determined. The determination may be based on one or more of: a pattern of detection of the one or more events, weather conditions, traveling wave analysis, grid operation actions, grid component actions, source or load connections or disconnections, measurement of a test signal injected into the grid, or location-specific sensor measurements. The pattern may include a temporal or frequency pattern. The temporal pattern may be determined from time-series data. The time-series data is obtained based on counts of detections or signal strength of each of the one or more events (such as PD that is indicative of deteriorating insulation) over a certain time-period. A higher count or signal strength per timespan or increasing or alternating trend may be precursor of a future fault. The frequency pattern may be determined from an analysis of frequency of signals associated with the events (such as PD signals associated with a PD event). In an embodiment, the analysis may be a Fourier Transform on the signals associated with the events, which may facilitate identification of characteristic harmonics associated with specific types of faults (such as those caused by arcing). The determination of the one or more locations where the events are detected may be further based on weather conditions correlated to event occurrences, traveling wave analysis for identifying fault locations by analyzing wave propagation characteristics caused by precursor events, or location-specific sensor measurements.

Temporal and geographic correlation of events may be used to identify specific components of the electric grid where faults are likely to occur. By analyzing the time-series patterns of event detection along with the geolocations of those events, specific grid components contributing to or affected by potential faults can be pinpointed. This combined approach enables a more accurate identification and prioritization of maintenance activities.

In an embodiment, the location is determined from weather conditions (determined based on measurements obtained from sensors such as wind, temperature, or humidity sensors) of a particular area and the location-specific sensor measurements because one or more sensors of the set of sensors located in an area may measure a parameter of a signal associated with an event. If the location of the one or more sensors are known, and if weather in the area matches the weather conditions, the event is located. Further, sensors such as accelerometers may detect vibrations and motion. The detected vibrations and motion are indicative of mechanical issues, abnormalities, structural anomalies, and so on, in components (such as substations, transformers, transmission lines, and so on) of the electric grid.

Furthermore, the traveling wave analysis may be performed on a traveling wave, which is generated at a particular location, where a component (such as a transmission line) of the electric grid is situated, due to sudden change in voltage or current. The change in the voltage or current may be an event, which can be detected by multiple traveling wave sensors. The locations of the traveling wave sensors and a time-difference between arrival of the traveling wave at the locations may be used to determine the location of the event. Traveling wave analysis may comprise detecting reflected waves generated at fault locations to determine their distance from the sensors. The analysis includes examining wave attenuation, polarity, and propagation time to classify the severity and type of fault. This approach enables a more accurate assessment of fault characteristics, leading to improved fault localization and faster response times. Traveling wave analysis may involve detecting wave propagation characteristics caused by one or more events, determining time differences in wave arrival at multiple sensors, and correlating these time differences with the locations of the detected events within the electric grid. This approach allows for accurate localization of faults, enabling faster response times and more precise maintenance actions.

The results of pattern detection and traveling wave analysis may be combined to refine fault location predictions. This combined approach allows for a more precise assessment of fault locations and provides a confidence score for each prediction, enabling operators to prioritize critical issues with higher accuracy.

Optionally, the one or more events are phenomena associated with probable occurrence of the one or more faults at the one or more determined locations. The phenomena may include one or more of PD, intermittent earthing, high-impedance earthing, lightning strike, circuit-breaker tripping, fuse blowing, abnormal current harmonics, abnormal voltage harmonics, sparking (due to a poor electrical contact), physical discontinuity of one or more conductors (i.e., breaking of the one or more conductors) in the electric grid, and leaking insulation. The PD may be classified as a corona discharge, a surface PD, a floating PD, an internal PD, a void PD, or a phase-synchronous sparking. The type of PD may be classified based on a temporal analysis of the PD signals. Based on the temporal analysis, a temporal pattern may be identified. The temporal pattern is identified on an oscillograph or a phase-resolved PD chart.

PD-like signals may be emitted by semiconductor devices, such as power supplies, inverters, and converters (as these semiconductor devices have known signal patterns), which should be labeled as noise, using, e.g. the temporal information that the signal amplitude of such noise typically stays at the same level for a long period of time, hours, days, or weeks, as compared to real PD signals the amplitude of which fluctuate much more. Single phase semiconductor noise typically has a maximum 1 or 2 times per mains frequency phase cycle. Additionally, some high-voltage AC/DC and DC/AC converters may generate noise pulses at 6 or 12 times per mains frequency cycle due to thyristor or IGBT switching actions, which information makes these easy to remove from the PD distance detection.

Also, partial discharge (PD) signals do not travel very far along the grid, unless the origin is a badly conducting component, such as a switch or a joint. But in those cases, there typically exists a phase signal deformation at the same specific moment as the spark signal is detected which is easy to notice. Therefore, a method to filter out some semiconductor device noise on high or medium voltage grids is to filter out those signals that travel very long distances.

After the detection of the one or more events and the determination of the one or more locations, the alert is generated. The alert includes the detected one or more events, the determined one or more locations, and one or more components of the electric grid in which the one or more events are detected. The alert corresponds to predictions of occurrences of the one or more faults. Optionally, the alert is a visual alert or a textual alert. The visual alert may include a map of a real-world region, signal strength, and/or a risk index associated with each event of the one or more events detected in the real-world region, and/or an urgency index associated with each event. The map includes one or more pointers, or heatmaps indicative of one or more geolocations corresponding to the one or more locations where the one or more events have been detected (i.e., where the one or more components are situated), and a topology map of the electric grid. The alert may include a topology map of the electric grid that displays fault locations identified using traveling wave analysis, as well as regions of concern highlighted based on pattern detection. This visual representation allows operators to quickly identify critical fault locations and areas of the grid that require further investigation or maintenance. The alert may dynamically update as additional data is received from event detection, location-specific sensors, traveling wave analysis, or pattern detection. This ensures that users have access to the most current information about fault locations, severity, and associated risk indices, enabling more informed decision-making and timely maintenance actions. The visual alert may further reflect patterns of event recurrence, providing users with insights into repeated occurrences of anomalies or faults within specific components or regions of the electric grid. This information helps operators identify persistent issues and prioritize maintenance efforts to prevent recurring faults.

The textual alert may include a link (such as a Uniform Resource Locator (URL)) of a webpage that directs to a visual alert. The visual alert may be generated by the processor. The processor may cause the visual alert to be rendered on a user interface (UI) of an application associated with predictive fault detection and maintenance of an electric grid. The application may be installed on a user device that may interact with the server to fetch the visual alert or the textual alert. The visual alert or the textual alert may be rendered on a display of the user device.

In an embodiment, a risk index, and an urgency index may be determined for each event of the one or more events. The determination of the risk index or the urgency index of an event of the one or more events is based on locations of the set of sensors (which may be obtained from a topology map of the grid that includes all components of the electric grid), a location of the one or more locations where the event is detected (and where a component, in which the event is detected, is situated) the parameters of a signal (i.e., an event signal associated with the event) propagating through the distribution network or the transmission network of the electric grid, a type to which the event is classified as, and association of the event as a precursor to a known fault occurring in a certain type of component in the electric grid. The risk and urgency indices may be dynamically generated based on the strength, frequency, and location of detected events. Events with higher signal strength, higher frequency of occurrence, or those located in critical areas of the grid are assigned higher risk and urgency scores. This dynamic assessment allows for prioritization of maintenance actions to address the most severe or urgent issues first. The alert may include a dynamically updating risk index and urgency index based on signal patterns, event severity, and historical trends. The alert may include a risk index and an urgency index derived from the strength, frequency, and recurrence of patterns identified by pattern detection, as well as the precision and severity indicated by traveling wave analysis. This combined approach ensures that operators can quickly assess the relative importance of different faults and prioritize actions based on the most critical risks. It further ensures that users and operators receive the most up-to-date information about the relative importance of different faults, allowing them to prioritize maintenance actions more effectively.

Optionally, the visual alert is generated based on one or more user inputs. The one or more user inputs are indicative of at least one of a time range, a time interval, a frequency, and a selection of an area on the map. The time range may include a starting timestamp and an ending timestamp. The one or more events are detected at the one or more geolocations within the time range. The time interval is one of a day, a week, or a month within the time range, or start and end times per user entry, i.e., a time range specifically provided by the user. The one or more events are detected at the one or more geolocations within the time interval. The map may indicate, via the heatmap and/or the pointer, the one or more locations where the one or more events were detected. The frequency is one of continuous or sporadic. The one or more geolocations may be determined based on detection of the one or more events within the time range. The one or more events are continuous phenomena or sporadic phenomena, i.e., the one or more events are detected continuously or sporadically. Based on selection of the area on the map, the one or more events, detected within the area of the map, may be rendered on the map.

Optionally, the user inputs may refine the temporal and spatial scope of fault analysis. For example, users can specify a time range to analyze events within a specific period or select a geographic area on the map to focus the analysis on events detected within that location. This approach allows for a more targeted and customized fault analysis.

Optionally, the visual alert further includes a histogram or a time-graph. The time-graph indicates count of events or signal strength detected at each time-instance of a set of time-instances within the time-range or the time-interval, one or more characteristics associated with each event of the one or more events, the risk index associated with each of the one or more events, and the urgency index associated with each of the one or more events. In an embodiment, the time-graph further indicates events detected at each time-instance of a set of time-instances within the selected area (which may be received as a user input).

Optionally, the visual alert further includes a list. Each entry of the list may include a component of the one or more components in which an event of the one or more events is detected, a type of the event detected, a time-instance of occurrence of the event, and a geolocation at which the event is detected. The time-instance may be within the time-range or the time-interval (which may be received as a user input).

Optionally, the one or more user inputs are indicative of a type of event or a component of the electric grid. The end-user may select a particular type of event or a certain component. Based on the selection, one or more events of the selected type or one or more events detected in the selected component may be detected. Thereafter, geolocations of the one or more events of the selected type or geolocation of the component are determined. The determined geolocations of the one or more events or the determined geolocation of the component may be rendered on the map. The histogram or time-graph may indicate time-instances during which the one or more events of the selected type were detected or time-instances during which the one or more events were detected in the component. The time-instances may be within the time-range or the time-period (which may be received as a user input). In an embodiment, the list may include one or more entries and each entry of the one or more entries includes at least one of: an event of the one or more events of the type and the component. One of the columns of the list will indicate the one or more events of the selected type, or the list may include one or more entries associated with the one or more events detected in the selected component.

Optionally, the map includes weather data at, or in vicinity of, the one or more geolocations corresponding to the one or more locations where the one or more events are detected. The histogram includes the weather data at the one or more locations during each time-instance of the set of time-instances. Further, each entry of the list includes the weather data at the geolocation included in the corresponding entry. The weather data includes one or more of temperature, humidity, wind speed, lightning condition, and thunderstorm condition. Based on selection of the area, where the one or more events have been detected, weather conditions at the area may be rendered. The weather conditions, within the area of the map, may be rendered on the map along with the heatmaps/pointers. The weather data may be dynamically linked to historical fault trends, allowing for a more comprehensive analysis of how environmental conditions impact the occurrence and severity of faults within the electric grid. This enables predictive analysis based on historical patterns to improve fault prediction accuracy.

Optionally, a predictive machine learning model is trained to execute at least one task. The execution of the at least one task enables generation of the alert. Optionally, components, amongst the set of components included in the electric grid, are classified based on detection of the one or more events. The classification is a result that may be obtained based on training the predictive machine learning model on ground truth data. The ground truth data may be a mapping between inputs corresponding to historical detections of events of the one or more events and outputs corresponding to the set of components in which the events are detected. For example, an event may be mapped to a certain component of the electric grid based on consistent detection of the event in the component. The predictive machine learning model is trained based on the mapping.

Furthermore, the machine learning model predicts a probability of an occurrence of each event of the one or more events at one or more time-instances in the one or more locations. The predictions may be based on weather forecasts at the one or more locations. The predictive machine learning model may be trained on ground truth data that comprises of correlation between inputs corresponding to historical detections of events of the one or more events and outputs corresponding to electrical load and/or weather conditions similar to the weather forecast. For example, if historically certain events have been detected in certain locations during certain weather conditions, then mapping between the detected events and the weather conditions may be established. The predictive machine learning model may be trained based on the mappings to generate the predictions. After a maintenance crew is dispatched to the indicated location of the precursor events, often the weather or other conditions have changed in such a way that the failing component does not anymore emit precursor signals, and the crew have trouble finding the actual broken component amongst multitude of grid components. The benefit of the above-mentioned event occurrence prediction based on load and weather conditions is that the maintenance crew can be sent out for investigations at a time when there is the highest probability of the failing component to emit the precursor signal.

The present disclosure also relates to a system. The system includes a set of sensors, a processor, and a display device. The processor may be included in a server. The display device may be included in a user device such as a smartphone. In the smartphone, an application that allows predictive maintenance of the electric grid, may be installed. The application may include a user interface, which may be controlled by the server to display the visual alert or the textual alert. The application may include instructions, which allow the smartphone to request the visual alert from the server or notify an end-user that the visual alert or the textual alert has been received from the server and is ready for rendering.

The present disclosure further provides aspects directed to prioritizing maintenance actions in an electric power grid based on precursor event data. The precursor event data used in the following aspects may be generated by detection of one or more events that are precursors of one or more faults in the electric grid, including by way of any of the detection, localization, pattern detection, travelling wave analysis, weather correlation, and sensor arrangements described in the foregoing passages.

In present context, the term “precursor event data” as used in the following passages refers to data generated by detection and measurement of one or more precursor events in the electric power grid, including information relating to characteristics of detected precursor events such as timing information, signal waveforms, amplitudes, energies, frequencies, and spatial locations. The term “precursor event” used in the following passages is consistent with the term “event” used in the foregoing passages.

The method according to the first aspect includes receiving precursor event data associated with a plurality of locations in the electric power grid. The precursor event data is received from one or more data sources, which may include a plurality of sensors deployed in the electric power grid, data storage systems, or data communication networks. The precursor event data contains measurements and characteristics of detected precursor events at the plurality of locations. Each location of the plurality of locations corresponds to a position in the electric power grid where one or more precursor events have been detected. The receiving of the precursor event data may be performed on a continuous basis as new precursor events are detected, or on a periodic basis at defined intervals. The precursor event data may be received in raw form or in a pre-processed form in which initial signal processing has been applied to the data.

The method according to the first aspect further includes computing, for each location of the plurality of locations, the plurality of independent priority dimensions based on the precursor event data. The computing of the plurality of independent priority dimensions involves three separate computational processes, one for each of the confidence metric, the urgency metric, and the impact metric. Each of the three computational processes operates on the precursor event data for a given location and produces a respective metric value for the given location. The three computational processes are performed independently of each other, such that the computation of one metric does not depend on the result of another metric. The computing of the plurality of independent priority dimensions is performed for each location of the plurality of locations, resulting in a set of three metric values for each location.

The computing of the confidence metric for a given location involves evaluating the precursor event data at the given location to determine a reliability of the precursor event data. The confidence metric is computed based on signal quality and statistical distribution characteristics of the precursor event data. Signal quality assessment includes evaluating a signal-to-noise ratio of the detected precursor events at the given location. Precursor events with a high signal-to-noise ratio are assigned a higher signal quality than precursor events with a low signal-to-noise ratio. Statistical distribution n characteristics assessment includes analyzing patterns of discharge activity at the given location to determine whether the patterns are characteristic of genuine localized insulation defects or whether the patterns are characteristic of random noise or interference. Genuine localized insulation defects produce characteristic patterns of discharge activity, whereas background noise and interference tend to produce random, non-localized distributions that are statistically distinct from genuine defects. The confidence metric further incorporates sensor agreement, wherein a higher degree of agreement among a plurality of sensors increases the confidence metric. The confidence metric also incorporates localization consistency, wherein a consistent determination of the location across multiple detection instances increases the confidence metric.

The computing of the urgency metric for a given location involves evaluating the precursor event data at the given location to determine a temporal development of precursor event activity. The urgency metric is computed based on a rate of change of an event frequency of the precursor event activity and an energy trajectory of the precursor event activity. The event frequency refers to a number of precursor events detected at the given location per unit time. The rate of change of the event frequency refers to how rapidly the event frequency is changing over time, such as whether the event frequency is increasing, decreasing, or remaining stable. A location at which the event frequency is rapidly increasing is assigned a higher urgency metric than a location at which the event frequency is stable, even if the absolute value of the event frequency is similar at both locations. The energy trajectory refers to a progression of signal amplitude, energy, or power of the precursor event activity at the given location over time. Increasing discharge energy over time is indicative of advancing insulation deterioration. The urgency metric applies time-series analysis methods and recency-weighted models, including moving average models, to assess the current state of the precursor event activity at the given location. The recency-weighted models ensure that the urgency metric reflects recent history of the precursor event activity without being dominated by transient spikes or by episodes that occurred in the distant past.

The computing of the impact metric for a given location involves determining a consequence of a fault at the given location. The impact metric is determined based on a topology of the electric power grid and an estimated loss of electrical load associated with the given location. The topology of the electric power grid defines the physical and electrical connections between the components of the electric power grid, including feeder configurations, branching structures, and interconnection points. The impact metric computation uses the topology to identify all downstream load branches that are connected through the given location. The estimated loss of electrical load is computed by aggregating the power consumption of all downstream load branches that would be disconnected in the event of a fault at the given location. A given location that connects to a large downstream load through a non-redundant path is assigned a higher impact metric than a given location that connects to a small downstream load or that has redundant paths available. The impact metric further incorporates assessment of network redundancy and network criticality, such that a given location in a densely loaded urban feeder with limited redundancy is assigned a higher impact metric than a given location on a peripheral spur with minimal connected load.

The method according to the first aspect further includes combining the confidence metric, the urgency metric, and the impact metric to generate the composite priority score for each location of the plurality of locations. The combining is performed by applying a combination function to the values of the confidence metric, the urgency metric, and the impact metric for a given location. The combination function may be implemented as weighted aggregation, in which each metric is multiplied by a respective weight and the weighted values are summed or otherwise combined. The combination function may alternatively be implemented as rule-based logic, in which predefined rules map combinations of metric values to priority scores. The combination function may alternatively be implemented using statistical models or machine learning models trained on historical data. The composite priority score represents a single, unified assessment of priority for each location that takes into account the reliability of the precursor event data, the temporal development of the precursor event activity, and the consequence of a fault at the location. The composite priority score is computed for each location of the plurality of locations, resulting in a set of composite priority scores that can be compared across the plurality of locations.

The method according to the first aspect further includes generating the ranked list of the plurality of locations based on the composite priority score for prioritizing the maintenance actions in the electric power grid. The generating of the ranked list involves ordering the plurality of locations according to the composite priority scores, with the location having the highest composite priority score positioned first in the ranked list and the location having the lowest composite priority score positioned last in the ranked list. The ranked list provides a prioritized ordering that identifies which locations in the electric power grid require maintenance actions with the highest priority. The ranked list enables maintenance resources to be directed toward locations where the combination of signal reliability, temporal deterioration, and network-level consequence is highest, rather than toward locations that merely exhibit a high volume of precursor events. The ranked list may be displayed on a user interface, transmitted to a maintenance management system, or used as an input to an automated maintenance scheduling process.

Optionally, the method according to the first aspect further comprises: detecting one or more precursor events using a plurality of sensors to generate the precursor event data; and determining the location for each precursor event of the one or more precursor events using a travelling-wave method.

The detecting of the one or more precursor events involves deploying a plurality of sensors in the electric power grid, wherein the plurality of sensors are configured to capture high-frequency transient signals associated with precursor events. The plurality of sensors may include electrical sensors, electromagnetic sensors, and travelling wave-based measurement sensors. The plurality of sensors operate at high sampling rates, such as sampling rates exceeding one megahertz (1 MHz), to capture low-energy, fast transient signals that are characteristic of precursor events at an early stage of insulation degradation. Each sensor of the plurality of sensors is positioned at a known location in the electric power grid and is configured to acquire signal data that is then transmitted as the precursor event data. The detecting of the one or more precursor events thereby generates the precursor event data that is received for computation of the plurality of independent priority dimensions.

The determining of the location for each precursor event of the one or more precursor events using the travelling-wave method involves analyzing travelling waves generated by the precursor event as the travelling waves propagate along conductors of the electric power grid. When a precursor event occurs at a location in the electric power grid, the precursor event generates travelling waves that propagate along the conductors in both directions from the location of the precursor event. The travelling waves arrive at the plurality of sensors at different times depending on a distance between each sensor and the location of the precursor event. The travelling-wave method determines the location of the precursor event by calculating the position along the conductor at which the precursor event occurred, based on the timing information received from the plurality of sensors. Each detected precursor event is thereby mapped to a specific location in the electric power grid, which enables the computation of the plurality of independent priority dimensions on a per-location basis.

The detection and localization of the one or more precursor events using the plurality of sensors and the travelling-wave method provides spatially resolved precursor event data for the computation of the plurality of independent priority dimensions. By determining the location for each precursor event, the method enables the confidence metric, the urgency metric, and the impact metric to be computed on a location-specific basis, which increases the specificity and usefulness of the ranked list. The use of the plurality of sensors operating at high sampling rates allows for detection of early-stage, low-energy precursor events that would not be detectable by conventional sensors operating at lower sampling rates, thereby extending the observable window of the degradation lifecycle and providing increased lead time for maintenance planning.

Optionally, the travelling-wave method comprises determining the location for each precursor event of the one or more precursor events based on differences in arrival times of travelling waves received at the plurality of sensors.

Herein, the differences in arrival times refer to the time offsets between when a travelling wave generated by a precursor event arrives at each respective sensor of the plurality of sensors. When a precursor event occurs at a location in the electric power grid, the resulting travelling waves propagate at a known or measurable velocity along the conductors. Because each sensor of the plurality of sensors is generally positioned at a different distance from the location of the precursor event, the travelling waves arrive at each sensor at a different time. The difference in arrival time between any two sensors of the plurality of sensors is a function of the difference in distance from each of the two sensors to the location of the precursor event. By measuring the differences in arrival times at the plurality of sensors and using the known propagation velocity, the travelling-wave method computes the location of the precursor event along the conductor. The determination of the location based on differences in arrival times provides a non-invasive, in-service method for spatial localization of precursor events without requiring physical access to the components of the electric power grid.

The use of differences in arrival times of travelling waves received at the plurality of sensors provides a spatially accurate determination of the location for each precursor event. This spatially accurate determination enables each precursor event to be associated with a specific component or segment of the electric power grid, which in turn enables the confidence metric, the urgency metric, and the impact metric to be computed with spatial specificity. The spatial accuracy of the location determination contributes to the accuracy of the impact metric because the impact metric is determined based on the topology of the electric power grid and the estimated loss of electrical load associated with the determined location.

Optionally, the travelling-wave method further comprises analyzing one or more of a propagation time, an attenuation, a polarity, and reflected waves to refine the location for each precursor event of the one or more precursor events.

The propagation time refers to the total time elapsed between the generation of the travelling wave at the location of the precursor event and the arrival of the travelling wave at a sensor. Analysis of the propagation time provides additional information about the distance between the precursor event and the sensor, which is used to refine the location determination. The attenuation refers to a reduction in amplitude of the travelling wave as the travelling wave propagates along the conductor. Analysis of the attenuation provides information about the distance and the characteristics of the conductor between the precursor event and the sensor, because different conductor types and conductor conditions produce different rates of attenuation. The polarity refers to the sign or direction of the travelling wave signal as received at the sensor. Analysis of the polarity provides information about the direction from which the travelling wave originated relative to the sensor and about the nature of the precursor event. The reflected waves refer to travelling waves that are reflected from discontinuities in the conductor, such as junctions, terminations, or impedance changes, and that arrive at the sensor after the initial travelling wave. Analysis of the reflected waves provides additional information about the topology of the conductor path between the precursor event and the sensor, which can be used to resolve ambiguities in the location determination.

The analysis of one or more of the propagation time, the attenuation, the polarity, and the reflected waves provides a refined location determination that is more accurate than a determination based solely on differences in arrival times. The refined location enables more accurate association of precursor events with specific components of the electric power grid, which contributes to increased accuracy in the computation of the confidence metric, the urgency metric, and the impact metric for each location.

Optionally, the precursor event data is associated with a partial discharge event or a high-impedance fault event.

A partial discharge event, as described herein, is a localized electrical discharge that only partially bridges the insulation between conductors. Partial discharge events occur within cracks, contaminants, or loose interfaces inside the insulation of a cable, a cable termination, an insulator of an overhead line, a surge voltage arrestor, loose contacts of joints, bad contacts of switchgear, or in insulation of switchgear, transformers, or galvanically connected sensor devices. Each partial discharge event is brief in duration and releases a small, fast burst of electromagnetic energy. While an individual partial discharge event causes only minor insulation damage, the cumulative effect of repeated partial discharge events erodes insulation steadily and accelerates degradation. Over time, partial discharge activity can intensify in both frequency and energy until the insulation reaches breakdown, resulting in a fault. Partial discharge activity can precede a fault by days, months, or years, making partial discharge events a leading indicator for predictive maintenance.

A high-impedance fault event refers to a fault condition characterized by a relatively low fault current. High-impedance fault events may be caused by a conductor which has fallen from an insulator or support, a conductor touching a galvanically floating metal object, a contaminant on a non-insulating switchgear component at high electric field, corona in unexpected places, or broken or high-impedance grounding. High-impedance fault events produce detectable high-frequency signals that can be captured by the plurality of sensors.

The association of the precursor event data with a partial discharge event or a high-impedance fault event enables the method according to the first aspect to address two categories of precursor events that are indicative of different types of degradation in the electric power grid. By computing the plurality of independent priority dimensions for precursor event data associated with partial discharge events and for precursor event data associated with high-impedance fault events, the method provides prioritization of maintenance actions for both categories of degradation. The confidence metric, the urgency metric, and the impact metric are applicable to both partial discharge events and high-impedance fault events, as both categories of precursor events exhibit signal quality characteristics, temporal development patterns, and location-dependent consequences that can be quantified.

Optionally, the method according to the first aspect further comprises filtering out the precursor event data having the confidence metric below a threshold prior to generating the ranked list of the plurality of locations.

The filtering involves comparing the confidence metric computed for each location of the plurality of locations against a predefined threshold value. If the confidence metric for a given location is below the threshold, the precursor event data associated with the given location is excluded from subsequent processing steps, including the generation of the composite priority score and the generation of the ranked list. The threshold may be set based on statistical analysis of historical precursor event data, operational requirements, or engineering judgement. The filtering may be implemented as a binary exclusion, in which the precursor event data below the threshold is completely removed, or as a down-weighting, in which the precursor event data below the threshold is assigned a reduced weight in the computation of the composite priority score.

The filtering out of the precursor event data having the confidence metric below the threshold reduces the number of false positive entries in the ranked list. Low-confidence precursor event data is likely attributable to noise, interference, or non-physical signals rather than genuine precursor event activity. By filtering out such low-confidence precursor event data prior to generating the ranked list, the method reduces the occurrence of non-actionable alerts and reduces alarm fatigue experienced by operators. The filtering ensures that only precursor event data that meets a minimum reliability standard is used to generate the ranked list, thereby increasing the credibility and utility of the prioritization output.

Optionally, generating the ranked list of the plurality of locations comprises assigning each location of the plurality of locations to one of a plurality of priority states, the plurality of priority states comprising a top state, an active state, and a closed state.

The top state indicates that the location has the highest priority and requires prompt attention by maintenance personnel. The active state indicates that the location has ongoing precursor event activity that warrants monitoring and near-term planning. The closed state indicates that the precursor event activity at the location has subsided or has been resolved. Each location of the plurality of locations is assigned to one of the plurality of priority states based on the composite priority score for the location. For example, locations having a composite priority score above a first threshold may be assigned to the top state, locations having a composite priority score between the first threshold and a second threshold may be assigned to the active state, and locations having a composite priority score below the second threshold or at which the precursor event activity has been resolved may be assigned to the closed state. It may be noted that the assignment of the plurality of priority states is not static; the assignment evolves as new precursor event data arrives and as patterns develop over time.

Such assignment of each location to one of the plurality of priority states provides a simple, three-tier classification scheme that gives operators an immediate and unambiguous indication of where attention should be directed. The top state identifies locations for which immediate maintenance actions are warranted. The active state identifies locations that should be monitored and for which maintenance actions should be planned. The closed state identifies locations at which precursor event activity has decreased or been addressed. A location may progress from the active state to the top state as the precursor event activity intensifies, or may transition to the closed state as the precursor event activity at the location stabilizes or is resolved. This dynamic classification ensures that the ranked list always reflects a current condition of the electric power grid.

Optionally, the method according to the first aspect further comprises: receiving a forecast of ambient conditions and a forecast of load conditions for a future time period; and modifying the composite priority score based on the forecast of ambient conditions and the forecast of load conditions.

The forecast of ambient conditions includes predicted values of environmental parameters such as temperature, humidity, and weather conditions for the future time period. The forecast of load conditions includes predicted values of electrical load and demand on the electric power grid for the future time period. For present purposes, the future time period may span from one day to five days or from one day to fourteen days, selected to be long enough to allow maintenance dispatch to be planned and resourced but short enough that the forecast remains reliable and relevant. It may be understood that the stress on components of the electric power grid varies with ambient temperature, humidity, load patterns, and seasonal demand cycles. For instance, insulation that is performing adequately under normal conditions may reach a failure threshold during a period of elevated temperature or during a period of peak electrical demand.

The modifying of the composite priority score based on the forecast of ambient conditions and the forecast of load conditions involves adjusting the composite priority score for each location to account for anticipated changes in stress on the components of the electric power grid. A location at which the precursor event activity is currently moderate may have the composite priority score increased if the forecast indicates that ambient conditions or load conditions during the future time period will increase stress on the component at the location. Conversely, a location at which the precursor event activity is currently elevated may have the composite priority score decreased or maintained if the forecast indicates that stress conditions during the future time period will decrease.

The incorporation of the forecast of ambient conditions and the forecast of load conditions enables the method to anticipate periods of peak stress on the components of the electric power grid and to recommend preemptive maintenance actions in advance of those periods. This forecast-based modification of the composite priority score shifts the maintenance approach from a reactive approach to a proactive approach, in which maintenance actions are planned and executed before adverse conditions occur rather than in response to the consequences of adverse conditions.

Optionally, the method according to the first aspect further comprises: generating a user interface comprising a topology map of the electric power grid; and rendering the ranked list of the plurality of locations on the topology map.

The user interface is a graphical display configured to present information to an operator or maintenance planner. The topology map is a visual representation of the topology of the electric power grid that shows the spatial relationship of components, feeders, branches, and interconnection points within the electric power grid. The generating of the user interface involves creating the topology map based on data defining the topology of the electric power grid, including the positions and connections of the components. The rendering of the ranked list on the topology map involves overlaying indications of the ranked list onto the topology map at the corresponding locations of the plurality of locations. The indications may include visual markers, color codes, numerical priority scores, or priority state indicators that identify each location and the associated priority.

The rendering of the ranked list on the topology map provides spatial context that enables operators to see not only which locations require attention but also where each location sits in the topology of the electric power grid, what each location is connected to, and how each location relates to other active events. This spatial presentation eliminates the need for operators to mentally construct a network-level picture from disaggregated outputs and enables intuitive interpretation of the prioritized information. Such topology map display enables operators to assess the network-level consequence of precursor event activity by visually tracing the connections between the affected location and the downstream load branches, thereby reinforcing the information captured in the impact metric.

Optionally, the method according to the first aspect further comprises generating a maintenance recommendation for at least one location of the ranked list of the plurality of locations, wherein the maintenance recommendation comprises one or more of an inspection instruction, a monitoring instruction, a scheduling of a planned outage, and a dispatch of a maintenance crew.

The maintenance recommendation is an actionable output generated by the method that specifies one or more actions to be taken at the at least one location. The inspection instruction directs maintenance personnel to perform a physical inspection of the component at the location to assess the condition of the component. The monitoring instruction directs maintenance personnel or the system to continue monitoring the precursor event activity at the location with increased frequency or increased sensitivity. The scheduling of a planned outage directs maintenance personnel to schedule a planned outage at the location during a low-demand period to perform maintenance or replacement of the component. The dispatch of a maintenance crew directs maintenance personnel to send a crew to the location within a specified timeframe to perform maintenance. The maintenance recommendation may be generated based on the composite priority score, the priority state, and the specific values of the confidence metric, the urgency metric, and the impact metric at the at least one location. For example, a location assigned to the top state with a high urgency metric and a high impact metric may receive a maintenance recommendation comprising a dispatch of a maintenance crew within 24 to 48 hours, while a location assigned to the active state with a moderate urgency metric may receive a maintenance recommendation comprising a monitoring instruction.

The generation of the maintenance recommendation provides automated decision support that eliminates the need for operators to manually interpret the ranked list and manually determine which maintenance actions to take. The maintenance recommendation translates the prioritized information from the ranked list into specific, actionable instructions that can be directly executed by maintenance personnel. This automation reduces the domain expertise required to operate the system and reduces the time between identification of a high-priority location and initiation of the appropriate maintenance response.

Optionally, the method according to the first aspect further comprises generating an asset-level fault source estimation by inferring a failing component type for at least one location of the plurality of locations based on the precursor event data and historical pattern recognition.

The asset-level fault source estimation involves determining a most probable type of component that is failing at the at least one location. The inferring of the failing component type is performed based on the precursor event data at the at least one location and historical pattern recognition. The historical pattern recognition involves comparing the characteristics of the precursor event data at the at least one location with patterns observed in historical datasets collected from prior precursor events at known component types. Statistical models or machine learning models trained on the historical datasets provide probabilistic guidance on the most probable source of observed precursor event activity. The failing component type may include, but is not limited to, a cable joint, a cable termination, switchgear, a transformer, an insulator, or a conductor. The asset-level fault source estimation informs the nature of the maintenance response, including the tools required for repair, the specialist skills needed, and the likely time required for repairs.

The generation of the asset-level fault source estimation adds an additional layer of information to the prioritization output by identifying not only where maintenance actions are required but also what type of component is most likely responsible for the observed precursor event activity. This information enables maintenance planners to prepare appropriate tools, materials, and personnel before dispatching a maintenance crew, which reduces the time and cost of the maintenance intervention.

Optionally, the method according to the first aspect further comprises dynamically updating the composite priority score and the ranked list of the plurality of locations based on a continuous reception of new precursor event data.

The dynamic updating involves continuously receiving new precursor event data from the electric power grid and recomputing the plurality of independent priority dimensions, the composite priority score, and the ranked list as the new precursor event data becomes available. Each time new precursor event data is received, the confidence metric, the urgency metric, and the impact metric are recomputed for the affected locations based on the updated precursor event data. The composite priority score is then regenerated for the affected locations, and the ranked list is updated to reflect the new composite priority scores. The dynamic updating ensures that the ranked list is current and reflects the latest condition of the electric power grid. A location may move from a lower position in the ranked list to a higher position if new precursor event data indicates increasing precursor event activity, and a location may move from a higher position to a lower position if new precursor event data indicates decreasing precursor event activity.

The dynamic updating of the composite priority score and the ranked list provides a continuously current view of the prioritization of maintenance actions in the electric power grid. Such dynamic updating eliminates reliance on static snapshots that become outdated as new precursor event data is collected. This continuous reception of new precursor event data and the continuous updating of the ranked list ensure that maintenance personnel are always working with the most current prioritization information, which enables timely response to changing conditions in the electric power grid.

The present disclosure also relates to the system for prioritizing maintenance actions in an electric power grid as described above. Various embodiments and variants disclosed above, with respect to the aforementioned computer-implemented method for prioritizing maintenance actions in an electric power grid according to the first aspect, apply mutatis mutandis to the system for prioritizing maintenance actions in an electric power grid according to the second aspect.

Optionally, in the system, the instructions further cause the system to: detect one or more precursor events using a plurality of sensors to generate the precursor event data; and determine the location for each precursor event of the one or more precursor events using a travelling-wave method based on differences in arrival times of travelling waves received at the plurality of sensors.

The system comprises the one or more processors and the memory storing instructions that, when executed by the one or more processors, cause the system to perform the detection of the one or more precursor events and the determination of the location for each precursor event. The plurality of sensors are communicatively coupled to the one or more processors and are configured to capture high-frequency transient signals associated with precursor events in the electric power grid. The one or more processors receive signal data from the plurality of sensors and process the signal data to detect the one or more precursor events. The one or more processors further determine the location for each precursor event using the travelling-wave method based on differences in arrival times of the travelling waves received at the plurality of sensors, as described in the context of the method according to the first aspect. The detection and localization functionality of the system provides the precursor event data that serves as input to the computation of the plurality of independent priority dimensions.

Optionally, in the system, the instructions further cause the system to filter out the precursor event data having the confidence metric below a threshold prior to generating the ranked list of the plurality of locations.

The system performs the filtering by comparing the confidence metric computed for each location against the threshold and excluding precursor event data associated with locations having the confidence metric below the threshold from subsequent processing, as described in the context of the method according to the first aspect. The filtering reduces the number of false positive entries in the ranked list generated by the system and increases the credibility of the prioritization output presented through the user interface.

Optionally, in the system, the instructions further cause the system to assign each location of the plurality of locations to one of a plurality of priority states, the plurality of priority states comprising a top state, an active state, and a closed state.

The system assigns each location to one of the plurality of priority states based on the composite priority score, as described in the context of the method according to the first aspect. The system dynamically updates the assignment of the plurality of priority states as new precursor event data is received and as the composite priority scores change. Such three-tier classification of locations into the top state, the active state, and the closed state provides an immediate and unambiguous indication to operators of where maintenance attention should be directed, as described in the context of the method according to the first aspect.

Optionally, in the system, the instructions further cause the system to: receive a forecast of ambient conditions and a forecast of load conditions for a future time period; and modify the composite priority score based on the forecast of ambient conditions and the forecast of load conditions.

The system receives the forecast of ambient conditions and the forecast of load conditions from one or more external data sources, such as weather forecasting services and load prediction systems. The one or more processors process the forecast data and modify the composite priority score for each location to account for anticipated changes in stress conditions during the future time period, as described in the context of the method according to the first aspect. The incorporation of forecast data enables the system to provide proactive scheduling of maintenance actions in advance of periods of peak stress on the components of the electric power grid.

Optionally, in the system, the instructions further cause the system to: generate a user interface comprising a topology map of the electric power grid; and render the ranked list of the plurality of locations on the topology map.

The system generates the user interface by rendering the topology map based on data defining the topology of the electric power grid. The system renders the ranked list on the topology map by overlaying indications of the ranked list at the corresponding locations, as described in the context of the method according to the first aspect. The user interface generated by the system presents the prioritized locations within the context of the topology of the electric power grid, enabling operators to see the spatial relationships between the prioritized locations and the downstream load branches connected through each location.

Optionally, in the system, the instructions further cause the system to generate a maintenance recommendation for at least one location of the ranked list of the plurality of locations, wherein the maintenance recommendation comprises one or more of an inspection instruction, a monitoring instruction, a scheduling of a planned outage, and a dispatch of a maintenance crew.

The system generates the maintenance recommendation based on the composite priority score, the priority state, and the specific values of the confidence metric, the urgency metric, and the impact metric at the at least one location, as described in the context of the method according to the first aspect. The maintenance recommendation generated by the system provides actionable instructions that can be directly executed by maintenance personnel, thereby automating the decision-support function and reducing the domain expertise required to operate the system.

Optionally, in the system, the instructions further cause the system to dynamically update the composite priority score and the ranked list of the plurality of locations based on a continuous reception of new precursor event data.

The system continuously receives new precursor event data from the plurality of sensors and recomputes the plurality of independent priority dimensions, the composite priority score, and the ranked list as the new precursor event data becomes available, as described in the context of the method according to the first aspect. The dynamic updating performed by the system ensures that the ranked list displayed on the user interface is current and reflects the latest condition of the electric power grid.

The present disclosure also relates to the computer-implemented method for prioritizing maintenance actions in an electric power grid according to the third aspect as described above. Various embodiments and variants disclosed above, with respect to the aforementioned computer-implemented method for prioritizing maintenance actions in an electric power grid according to the first aspect and the aforementioned system for prioritizing maintenance actions in an electric power grid according to the second aspect, apply mutatis mutandis to the computer-implemented method for prioritizing maintenance actions in an electric power grid according to the third aspect.

Optionally, in the method according to the third aspect, the travelling-wave method further comprises analyzing one or more of a propagation time, an attenuation, a polarity, and reflected waves to refine the location for each precursor event of the one or more precursor events.

The method according to the third aspect performs the analysis of one or more of the propagation time, the attenuation, the polarity, and the reflected waves in addition to the analysis of the differences in arrival times, to refine the location determination for each precursor event of the one or more precursor events. The propagation time refers to the total time elapsed between the generation of the travelling wave at the location of the precursor event and the arrival of the travelling wave at a sensor of the plurality of sensors. The attenuation refers to a reduction in amplitude of the travelling wave as the travelling wave propagates along the conductors of the electric power grid. The polarity refers to the sign or direction of the travelling wave signal as received at the sensor. The reflected waves refer to travelling waves that are reflected from discontinuities in the conductors, such as junctions, terminations, or impedance changes, and that arrive at the sensor after the initial travelling wave. The analysis of one or more of the propagation time, the attenuation, the polarity, and the reflected waves in the method according to the third aspect provides a refined location determination that is more accurate than a determination based solely on differences in arrival times, as described in the context of the method according to the first aspect. The refined location in the method according to the third aspect enables more accurate association of the one or more precursor events with specific components of the electric power grid, which contributes to increased accuracy in the computation of the confidence metric, the urgency metric, and the impact metric for each location of the plurality of locations.

Optionally, the method according to the third aspect further comprises filtering out the precursor event data having the confidence metric below a threshold prior to generating the ranked list of the plurality of locations.

The filtering in the method according to the third aspect involves comparing the confidence metric computed for each location of the plurality of locations against a predefined threshold value. If the confidence metric for a given location is below the threshold, the precursor event data associated with the given location is excluded from subsequent processing steps, including the generation of the composite priority score and the generation of the ranked list. The threshold may be set based on statistical analysis of historical precursor event data, operational requirements, or engineering judgement. The filtering in the method according to the third aspect reduces a number of false positive entries in the ranked list by excluding precursor event data that is likely attributable to noise, interference, or non-physical signals rather than genuine precursor event activity, as described in the context of the method according to the first aspect. The filtering thereby increases the credibility and utility of the prioritization output generated by the method according to the third aspect and reduces alarm fatigue experienced by operators.

Optionally, the method according to the third aspect further comprises dynamically updating the composite priority score and the ranked list of the plurality of locations based on a continuous reception of new precursor event data.

The dynamic updating in the method according to the third aspect involves continuously receiving new precursor event data generated by the detecting of further precursor events using the plurality of sensors and by the determining of locations for the further precursor events using the travelling-wave method. Each time new precursor event data is received, the confidence metric, the urgency metric, and the impact metric are recomputed for the affected locations based on the updated precursor event data. The composite priority score is then regenerated for the affected locations, and the ranked list is updated to reflect the new composite priority scores. The dynamic updating in the method according to the third aspect ensures that the ranked list reflects the latest condition of the electric power grid, such that a location may move higher in the ranked list when the new precursor event data indicates increasing precursor event activity, and a location may move lower in the ranked list when the new precursor event data indicates decreasing precursor event activity, as described in the context of the method according to the first aspect. The dynamic updating of the composite priority score and the ranked list in the method according to the third aspect thereby provides a continuously current view of the prioritization of the maintenance actions in the electric power grid.

Optionally, in the method according to the third aspect, generating the ranked list of the plurality of locations comprises assigning each location of the plurality of locations to one of a plurality of priority states, the plurality of priority states comprising a top state, an active state, and a closed state.

The top state indicates that the location has the highest priority and requires prompt attention by maintenance personnel. The active state indicates that the location has ongoing precursor event activity that warrants monitoring and near-term planning. The closed state indicates that the precursor event activity at the location has subsided or has been resolved. Each location of the plurality of locations is assigned to one of the plurality of priority states based on the composite priority score for the location, as described in the context of the method according to the first aspect. In the method according to the third aspect, the assignment of the plurality of priority states is not static; the assignment evolves as new precursor event data arrives through the detecting step and the travelling-wave localization step, and as patterns develop over time. A location may progress from the active state to the top state as the precursor event activity intensifies, or may transition to the closed state as the precursor event activity at the location stabilizes or is resolved. The assignment of each location to one of the plurality of priority states in the method according to the third aspect provides a simple, three-tier classification scheme that gives operators an immediate and unambiguous indication of where attention should be directed.

In an embodiment, the combining of the confidence metric, the urgency metric, and the impact metric to generate the composite priority score is performed using one or more alternative mathematical formulations. In one implementation, the composite priority score is computed as a harmonic mean of the confidence metric, the urgency metric, and the impact metric, such that lower values in any one of the plurality of independent priority dimensions reduce the composite priority score disproportionately. In another implementation, the composite priority score is computed as a geometric mean of the confidence metric, the urgency metric, and the impact metric, thereby preserving proportional relationships between the plurality of independent priority dimensions. In a further implementation, the composite priority score is determined as a minimum of the confidence metric, the urgency metric, and the impact metric, such that the composite priority score is constrained by a weakest contributing dimension. In a yet further implementation, the composite priority score is generated using a rule-based model, a decision tree model, or a trained machine learning model that maps the plurality of independent priority dimensions to a prioritization outcome.

In an embodiment, the impact metric is computed using one or more alternative formulations based on electrical parameters, geographic parameters, or user-defined parameters. In one implementation, the impact metric is computed using a linear function that maps an estimated current at the location to an impact value, wherein zero current corresponds to zero impact and a configurable threshold current corresponds to a maximum impact value. In another implementation, the impact metric is computed using a non-linear function, including a sigmoidal function or a step-wise function, to reflect non-linear consequences of load interruption. In a further implementation, the impact metric is determined based on user-defined importance levels assigned to different areas or assets within the electric power grid. In a yet further implementation, the impact metric is determined based on geographic analysis or map-based analysis of surrounding infrastructure, including identification of the critical infrastructure derived from an external geographic information system.

In an embodiment, the impact metric incorporates map-based enrichment using external geographic information system data. The one or more processors retrieve map data from one or more external geographic databases and identify the critical infrastructure including hospitals, industrial facilities, data centers, communication hubs, or other predefined assets. The impact metric is increased based on proximity of a precursor event location to the critical infrastructure, wherein the proximity is determined using geographic distance or electrical distance within the topology of the electric power grid, or a combination of the geographic distance and the electrical distance. The impact metric may further incorporate a density of critical infrastructure within a predefined area surrounding the location. In a further embodiment, the impact metric is determined by combining geographic proximity with electrical connectivity to the identified critical infrastructure.

In an embodiment, the impact metric is further modified based on an ability of a load or a consumer associated with the location to operate in an islanded mode. The one or more processors determine whether the load is capable of self-supply using local generation, energy storage, or microgrid operation. When an islanding capability is present, the impact metric is decreased proportionally to a degree of self-sufficiency of the load, based on parameters including available generation capacity, energy storage capacity, or expected duration of islanded operation. The decrease in the impact metric may be applied conditionally based on forecast operating conditions, such that the decrease is applied only when the islanding capability is expected to be available during a future time period.

In an embodiment, the confidence metric is computed as a product of a quality component and a sufficiency component. The quality component is based on a fraction of signal locations without detected issues, and the sufficiency component is based on a number of signal locations without detected issues. The confidence metric further incorporates detection of signal issues including non-uniform signal distributions, narrow clusters, missing sensor detections, and time-of-day clustering patterns. The confidence metric may additionally be computed based on energy levels of precursor events, temporal continuity or intermittency of precursor events, and a number of sensors detecting the precursor events.

In an embodiment, the confidence metric is computed using pattern recognition applied to phase-resolved partial discharge plots. The pattern recognition comprises detecting cluster characteristics including shape, width, periodicity, and symmetry of discharge patterns. The confidence metric may further be computed using a trained machine learning model configured to distinguish genuine precursor event activity from noise or interference.

In an embodiment, the confidence metric is decreased when the precursor event data exhibits a signal pattern corresponding to a known disturbance source present in a healthy grid. The known disturbance source may include a semiconductor-based device, an inverter, a converter, a switch-mode power supply, an electric vehicle charging station, a battery energy storage system, or a generator. The one or more processors compare detected signal patterns with reference patterns associated with normal operation of such devices and decrease the confidence metric when a similarity exceeds a threshold. The decrease may be performed using a classifier trained to distinguish precursor event activity from benign signal disturbances.

In an embodiment, the confidence metric is dynamically adjusted based on user feedback. The one or more processors receive user input indicating that a detected precursor event location is invalid or not relevant. In response to the user input, the confidence metric associated with the detected precursor event location is decreased, and the user input is stored for updating models used in computing the confidence metric. The decrease in the confidence metric may be proportional to a number of user invalidations associated with the detected precursor event location.

In an embodiment, the urgency metric is extended to include predictive modelling of component degradation. The urgency metric comprises predicting future degradation or failure of a component using time-series analysis or machine learning models. The machine learning models may include a random forest model, a gradient boosting model, a neural network, a recurrent neural network, a long short-term memory network, or a transformer-based model. The urgency metric may further incorporate changes in phase-resolved partial discharge patterns over time.

In an embodiment, the method further comprises computing a severity metric indicative of a current damage level of a component. The severity metric is based on parameters including event frequency, event energy, spark repetition rate, or other signal characteristics. The urgency metric may be defined as a rate of change of the severity metric, thereby separating an instantaneous damage state from a temporal development of the damage state.

In an embodiment, the method further comprises computing a location accuracy metric indicative of an uncertainty in a determined location of precursor events. The location accuracy metric is based on spatial dispersion of detected signal locations, statistical spread including a minimum-maximum range or a standard deviation, and measurement uncertainty associated with sampling resolution. The location accuracy metric may further incorporate a fraction of precursor events with uncertain or missing locations.

In an embodiment, the method further comprises clustering signal locations into observations representing underlying fault phenomena. The clustering may be performed using a density-based clustering algorithm, including OPTICS or HDBSCAN, and may be implemented on a graph representation of signal locations. Signal locations may be weighted based on signal properties including energy or severity. Clusters may be merged based on similarity of signal characteristics, including similarity in phase-resolved patterns, sensor participation, or time-of-day characteristics.

In an embodiment, a frequency of computing the composite priority score is dynamically adjusted. The frequency is increased for locations with a higher urgency metric or a higher impact metric and is decreased for stable locations. The adjustment may further depend on forecast environmental conditions, including wind, precipitation, humidity, soil moisture, or a wildfire risk index. The frequency may alternatively be configurable by a user.

In an embodiment, the method further comprises operating in one of a plurality of operational modes, including a normal operation mode, a storm response mode, a wildfire mitigation mode, or a long-term asset management mode. Each operational mode utilizes different weighting, time horizons, or computational parameters for the plurality of independent priority dimensions.

In an embodiment, the method further comprises constructing a digital twin of at least a portion of the electric power grid using heterogeneous data sources including monitoring data, weather data, maintenance records, thermal imaging data, transformer oil analysis data, and outage records. The digital twin is used to generate a risk field or a probability field across the electric power grid, which is used to prioritize candidate locations.

In an embodiment, the method further comprises aligning multi-modal data associated with a candidate event according to a common time reference and jointly validating the candidate event using the aligned multi-modal data. The multi-modal data may include electrical disturbance data, user voltage data, and text-based outage reports. Validated events may be used to generate feature tensors representing fault mechanisms using time-frequency analysis.

In an embodiment, the method further comprises distinguishing between transient fault events and permanent fault events based on restoration behavior following automatic restoration attempts. Transient fault events may be stored as weak signals indicative of future risk.

In an embodiment, the method further comprises locating a root-cause component by performing topology-constrained upstream tracing and forward fault propagation simulation. A confidence score is computed for each candidate component based on a match between simulated propagation and measured data.

In an embodiment, the method further comprises computing a validation factor based on a comparison between predicted risk values and diagnosis confidence values. A dynamic conservatism coefficient is derived from the validation factor and is used to constrain generation of maintenance actions or switching sequences.

In an embodiment, the method further comprises generating and evaluating candidate switching sequences or candidate restoration sequences for fault isolation and load transfer. The candidate switching sequences or candidate restoration sequences are pruned based on the dynamic conservatism coefficient.

In an embodiment, the method further comprises storing event data, feature data, diagnosis data, and action outcome data as standardized knowledge cases. The standardized knowledge cases are used to generate adversarial simulation scenarios, identify shortcomings in system response, and update prediction models.

In an embodiment, the method further comprises forecasting load values or distributed generation production values for a plurality of nodes of the electric power grid and performing load flow analysis using the forecast values. The composite priority score may be adjusted based on predicted voltage alarm significance or predicted current alarm significance derived from the load flow analysis. Forecasting models may include transformer neural networks, recurrent neural networks, or hybrid architectures.

In an embodiment, the method further comprises computing an alarm significance value based on a probabilistic deviation of a signal from a threshold, weighted by a consequence factor indicative of affected consumers.

In an embodiment, the method further comprises determining corrective grid reconfiguration actions using a reinforcement learning model trained to reduce cumulative alarm significance. The reinforcement learning model may be trained using proximal policy optimization and may output switching configurations subject to topology constraints.

In an embodiment, at least part of the method is deployed on an edge computing platform located at a substation or at a field location. The edge computing platform processes sensor data locally and transmits derived features or alerts to a central system.

In an embodiment, the method further comprises generating augmented-reality or interactive visualizations of asset condition, predicted failures, or recommended maintenance actions.

In an embodiment, the method further comprises integrating the ranked list with asset investment planning by using predicted degradation, remaining useful life, or predicted failure probability.

In an embodiment, the method further comprises generating work orders based on the ranked list and receiving repair reports following execution of the work orders. The repair reports are used to update models associated with the confidence metric, the urgency metric, the impact metric, and the composite priority score, thereby forming a closed feedback loop.

In an embodiment, the impact metric is normalized relative to one or more reference locations, reference feeders, or predefined baseline operating conditions within the electric power grid. Such normalization enables comparison of impact values across different regions of the electric power grid that may otherwise have differing load magnitudes, topology characteristics, or operational conditions.

In an embodiment, the method further comprises predicting a future location of a fault based on historical precursor event data, spatial clustering behavior, and temporal progression patterns of precursor event activity. The prediction may further incorporate asset characteristics, environmental conditions, component age, and historical failure patterns to estimate both a probable location and a probable time of occurrence of a future fault.

In an embodiment, the method further comprises computing a correction-effort metric indicative of an expected effort required to remedy a fault condition at a given location. The correction-effort metric may be based on historical repair data, labor-hours, required equipment, accessibility of the location, or shared effort associated with multiple related faults. The correction-effort metric may be combined with one or more of the confidence metric, the urgency metric, and the impact metric to perform multi-objective prioritization.

In an embodiment, the composite priority score is further determined based on an intersection of two or more prioritization measures, such that locations exhibiting simultaneously high values across multiple dimensions, including event frequency, severity, or correction effort, are prioritized over locations exhibiting high values in only a single dimension.

In an embodiment, the impact metric is computed as a ratio of a current associated with a precursor event location to an average current measured at one or more reference sensors. The one or more reference sensors may be predefined for a portion of the electric power grid and may represent typical or baseline operating conditions. Parameters used in computing the impact metric may be configurable on a per-line basis, and the impact metric may further be based on a length of a line associated with the location, a type of component associated with the precursor event data, or a number of phases present at the location.

In an embodiment, the impact metric is computed using a plurality of alternative calculation methods, and a fallback method of the plurality of alternative calculation methods is selected when one or more of the plurality of alternative calculation methods is unavailable due to missing data, communication failure, or insufficient measurement coverage.

In an embodiment, the method further comprises detecting vegetation contact or similar external disturbances using auxiliary indicators, including an increase in neutral voltage or imbalance conditions in the electric power grid. In a related embodiment, intermittent fault causes, including animal interaction, vegetation contact, degraded connections, or conductor movement, are identified by analyzing waveform data using signal processing techniques, machine learning models, or high-frequency signal characteristics.

In an embodiment, locations associated with a confidence metric below a threshold are hidden from a default view of the user interface to reduce visual clutter and operator distraction. In such embodiments, the urgency metric and the impact metric for the hidden locations may optionally be computed under an assumption that the precursor event data originates from a failing component, thereby preserving analytical continuity while limiting visual prominence.

In an embodiment, the method further comprises performing an economic optimization to allocate maintenance resources based on the composite priority score. The economic optimization may determine an allocation of time, personnel, and equipment resources that minimizes an expected cost, an expected risk, or a service interruption metric subject to operational constraints.

In an embodiment, the method further comprises generating timing recommendations for maintenance actions, wherein the timing recommendations indicate when maintenance actions, including inspection, repair, replacement, or cleaning, should be performed based on predicted degradation rates, forecast operating conditions, and resource availability.

In an embodiment, precursor event activity is predicted by identifying temporal correlations between partial discharge strength, steady-state signal behavior, and load forecast data. Such prediction may enable early identification of emerging fault conditions before a significant increase in precursor event frequency is observed.

In an embodiment, the method further comprises predicting a component associated with a precursor event based on signal characteristics, spatial location, and historical pattern recognition. The predicted component may include, but is not limited to, a cable joint, a cable termination, an insulator, a transformer, or switchgear.

In an embodiment, the method further comprises generating alerts based on precursor events using an enhanced alert mechanism. The enhanced alert mechanism may incorporate the composite priority score, threshold-based triggering, temporal persistence criteria, and correlation across multiple data sources to reduce false positives and improve relevance of alerts.

In an embodiment, the frequency of computing the composite priority score is configurable by a user and may be automatically adjusted based on one or more of weather conditions, forecast conditions, crew availability, or precursor event activity levels.

In an embodiment, the confidence metric, the urgency metric, the impact metric, or the composite priority score is further refined using additional data sources, including historical alarm classifications, intervals between alarms, and contextual operational data.

In an embodiment, the method further comprises forecasting one or more load values or distributed generation production values for a plurality of nodes of the electric power grid and performing load flow analysis using the forecast values. At least one of the confidence metric, the urgency metric, the impact metric, or the composite priority score may be adjusted based on a predicted voltage alarm significance or a predicted current alarm significance derived from the load flow analysis.

In an embodiment, the method further comprises computing an alarm significance value using a probabilistic deviation function based on a deviation of a signal from a threshold, and weighting the alarm significance value by a consequence factor indicative of a number of affected consumers.

In an embodiment, the method further comprises integrating prioritization outputs with reinforcement learning models configured to determine corrective grid reconfiguration actions, including selection of switching configurations for circuit breakers while maintaining a desired topology of the electric power grid.

In an embodiment, the method further comprises determining the locations of one or more signal sources using alternative localization techniques in place of, or in combination with, the travelling-wave method. The alternative localization techniques include signal strength comparison across the plurality of sensors, predefined sensor coverage zones, or topology-based inference, and the precursor event data is associated with the determined locations for subsequent computation of the plurality of independent priority dimensions.

In an embodiment, the precursor event data is received with predefined location associations corresponding to positions of the plurality of sensors, and no explicit localization step is performed. In such an embodiment, each sensor of the plurality of sensors is associated with a predefined monitored portion of the electric power grid, and precursor events detected by a given sensor are attributed to the predefined monitored portion associated with the given sensor.

In an embodiment, the plurality of independent priority dimensions comprises a reduced set of metrics, including the urgency metric and the impact metric, wherein the confidence metric is omitted or implicitly incorporated into one or both of the urgency metric and the impact metric. The composite priority score is generated based on the reduced set of metrics.

In an embodiment, the composite priority score is computed directly from the precursor event data using a single analytical model, without explicit separate computation of the confidence metric, the urgency metric, and the impact metric. The single analytical model may comprise a trained machine learning model that implicitly captures relationships corresponding to confidence, urgency, and impact within parameters of the trained machine learning model.

In an embodiment, the urgency metric is computed based on a temporal variation of signal activity without requiring explicit attribution of signals to a location using arrival time analysis. In such an embodiment, temporal development of signal activity observed at a given sensor or a group of sensors is used as a basis for the urgency metric.

In an embodiment, the impact metric is determined based solely on a number of users associated with the location, without explicitly analyzing the topology of the electric power grid. The number of users may be derived from customer records, metering infrastructure, or other data sources that associate users with portions of the electric power grid.

In an embodiment, locations are prioritized using rule-based logic that evaluates the urgency metric and the impact metric without generating a numerical composite priority score. The rule-based logic may assign locations to ordered priority categories based on predefined combinations of the urgency metric and the impact metric.

In an embodiment, locations exceeding a predefined threshold of priority are identified for maintenance actions without generating an ordered ranked list. In such an embodiment, the composite priority score is compared with the predefined threshold, and locations satisfying the predefined threshold are reported to the user interface as candidates for maintenance actions.

In an embodiment, prioritization is performed at a level of individual precursor events rather than aggregated locations, wherein each precursor event is assigned a priority value based on signal characteristics and temporal behavior of the precursor event. Individual precursor events may subsequently be aggregated into location-level prioritization if required.

In an embodiment, the method is applied to an electrical system comprising a subset of grid components, including an industrial distribution system or an isolated network, rather than a complete electric power grid. In such an embodiment, the topology used in computing the impact metric corresponds to the subset of grid components, and the plurality of sensors is deployed within the subset of grid components.

In an embodiment, the plurality of sensors operates without strict time synchronization, and approximate localization of signal sources is performed using relative timing or using signal characteristics. In such an embodiment, the arrival time analysis is adapted to accommodate timing drift or timing offset across the plurality of sensors, and the confidence metric may reflect additional uncertainty introduced by reduced time synchronization.

In an embodiment, a machine learning model is employed to generate a priority value directly from the precursor event data, wherein the machine learning model implicitly captures relationships corresponding to confidence, urgency, and impact without explicit separate computation of the confidence metric, the urgency metric, and the impact metric.

In a further embodiment, the various metrics, predictions, and prioritization outputs described herein may be computed using one or more machine learning models, statistical models, rule-based systems, or hybrid approaches, and may be updated over time using newly acquired data, user feedback, or recorded maintenance outcomes.

In a further embodiment the present disclosure provides a computer-implemented method for prioritising maintenance actions in an electric power grid, the method comprising:
finding locations of one or more grid fault or signal sources in the electric power grid using arrival time analysis of the signals originated or caused by the said signal sources, the signals recorded by a plurality of data network connected sensors monitoring the grid conductors and components at geographically distributed locations along the grid circuits and branches;
receiving precursor event data associated with the plurality of locations in the electric power grid;
computing, for each location of the plurality of locations, a plurality of independent priority dimensions based on the precursor event data, the plurality of independent priority dimensions comprising:
(a) a confidence metric indicative of a reliability of the precursor event data at the location, wherein the confidence metric is computed based on signal characteristics of the precursor event data;
(b) an urgency metric indicative of a temporal development of precursor signal activity at the location, wherein the urgency metric is computed based on a rate of change of signal activity emitted from the location which can be identified to originate from that location using analysis of signal arrival times; and
(c) an impact metric indicative of a consequence of a fault at the location, wherein the impact metric is determined based on a topology of the electric power grid and an estimated loss of electrical load or number of users associated with the location;
combining the confidence metric, the urgency metric, and the impact metric to generate a composite priority score for each location of the plurality of locations; and
generating a ranked list of the plurality of locations based on the composite priority score for prioritising the maintenance actions in the electric power grid.

In an embodiment, a computer-implemented method is provided wherein a plurality of sensors are deployed at geographically distributed locations in an electric power grid and are communicatively coupled via a data network. The sensors are configured to detect signals associated with precursor events. The method comprises determining locations of one or more signal sources by performing arrival time analysis of the signals recorded at the plurality of sensors, wherein differences in arrival times are used to estimate a position of each signal source along grid conductors. Precursor event data is associated with the determined locations. For each location, a plurality of independent priority dimensions is computed, comprising a confidence metric based on signal characteristics including signal-to-noise ratio and waveform consistency, an urgency metric based on a rate of change of signal activity identified as originating from the location, and an impact metric based on a topology of the electric power grid and an estimated loss of electrical load. The metrics are combined to generate a composite priority score, and a ranked list of locations is generated based on the composite priority score.

In an embodiment, the arrival time analysis comprises grouping signals detected across multiple sensors into clusters corresponding to a common source and determining the location of each cluster based on consistent time differences of arrival. The urgency metric is computed using temporal evolution of cluster activity, including an increase in cluster density and repetition rate. The confidence metric is increased when multiple sensors consistently detect signals associated with the same location. The ranked list prioritises locations based on combined evaluation of confidence, urgency, and impact.

In an embodiment, the method is performed continuously in real time, wherein precursor event data is received as a data stream from the plurality of sensors. Arrival time analysis is applied to each newly detected signal to update location estimates. The confidence metric, urgency metric, and impact metric are recomputed dynamically as new data is received. The ranked list is updated in real time to reflect a current state of the electric power grid.

In an embodiment, the impact metric is determined using real-time or historical load data associated with downstream branches connected to each location. The impact metric further incorporates weighting factors based on critical infrastructure supplied by the location. Locations supplying critical loads are assigned higher impact values relative to locations supplying non-critical loads.

In an embodiment, the urgency metric is computed based on both a rate of change of signal frequency and an energy trajectory of the signal activity. Increasing signal amplitude, increasing event rate, and accelerating temporal trends contribute to higher urgency values.

In an embodiment, the confidence metric is computed using pattern recognition applied to signal characteristics, wherein signals matching known disturbance patterns associated with normal operation of grid-connected equipment are assigned lower confidence values. Signals exhibiting characteristics of genuine precursor events are assigned higher confidence values.

In an embodiment, the arrival time analysis is refined by incorporating additional signal properties including attenuation, polarity, and reflected wave characteristics to improve localisation accuracy.

In an embodiment, the ranked list is rendered on a user interface comprising a topology map of the electric power grid, wherein each location is displayed with an associated composite priority score and visual indicators representing the confidence metric, urgency metric, and impact metric.

In an embodiment, locations of signal sources are determined using alternative localisation techniques, including signal strength comparison or predefined sensor coverage zones, without requiring arrival time analysis. Precursor event data is associated with the determined locations, and priority metrics are computed to generate a ranked list.

In an embodiment, precursor event data is received with predefined location associations corresponding to sensor positions, and no explicit localisation step is performed. The method proceeds by computing priority metrics for each location and generating a ranked list.

In an embodiment, the plurality of priority dimensions comprises a reduced set of metrics, including an urgency metric and an impact metric, wherein the confidence metric is omitted or implicitly incorporated. The composite priority score is generated based on the reduced set of metrics.

In an embodiment, a composite priority score is computed directly from precursor event data using a single analytical model, without explicitly computing separate confidence, urgency, and impact metrics.

In an embodiment, the urgency metric is computed based on temporal variation of signal activity without requiring explicit attribution of signals to a location using arrival time analysis.

In an embodiment, the impact metric is determined based solely on a number of users associated with a location, without explicitly analysing the topology of the electric power grid.

In an embodiment, locations are prioritised using rule-based logic that evaluates urgency and impact without generating a numerical composite priority score.

In an embodiment, locations exceeding a predefined threshold of priority are identified for maintenance actions without generating an ordered ranked list.

In an embodiment, prioritisation is performed at a level of individual precursor events rather than aggregated locations, wherein each event is assigned a priority value based on signal characteristics and temporal behaviour.

In an embodiment, the method is applied to an electrical system comprising a subset of grid components, including industrial distribution systems or isolated networks, rather than a full electric power grid.

In an embodiment, the plurality of sensors operates without strict time synchronisation, and approximate localisation of signal sources is performed using relative timing or signal characteristics.

In an embodiment, a machine learning model is employed to generate a priority score directly from precursor event data, wherein the model implicitly captures relationships corresponding to confidence, urgency, and impact without explicitly computing separate metrics.

In an embodiment, a computer-implemented method is provided wherein a plurality of sensors are deployed at geographically distributed locations in an electric power grid and are communicatively coupled via a data network. The sensors are configured to detect signals associated with precursor events occurring in components of the electric power grid. The method comprises receiving precursor event data generated by the plurality of sensors, wherein the precursor event data is associated with a plurality of locations in the electric power grid based on a predefined association between each sensor and a corresponding monitored portion of the grid, or based on signal characteristics including signal strength, sensor proximity, or topology-based inference, without performing arrival time analysis of the signals.

For each location of the plurality of locations, a plurality of independent priority dimensions is computed based on the precursor event data. The plurality of independent priority dimensions comprises a confidence metric indicative of a reliability of the precursor event data at the location, wherein the confidence metric is computed based on signal characteristics including signal-to-noise ratio, waveform consistency, and persistence of detected activity; an urgency metric indicative of a temporal development of precursor signal activity at the location, wherein the urgency metric is computed based on a rate of change of signal activity over time associated with the location; and an impact metric indicative of a consequence of a fault at the location, wherein the impact metric is determined based on a topology of the electric power grid and an estimated loss of electrical load or number of users associated with the location.

The method further comprises combining the confidence metric, the urgency metric, and the impact metric to generate a composite priority score for each location of the plurality of locations. The method further comprises generating a ranked list of the plurality of locations based on the composite priority score for prioritising maintenance actions in the electric power grid.

### DETAILED DESCRIPTION OF THE DRAWINGS

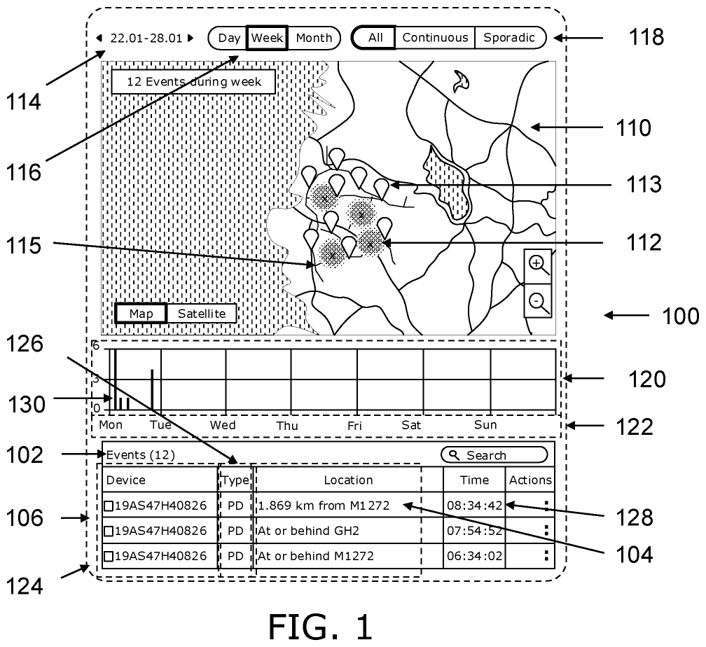

Referring to FIG. 1, there is illustrated an exemplary visual alert 100 that corresponds to prediction of faults in an electric grid, in accordance with an embodiment of the present disclosure. The visual alert 100 includes one or more events 102 that are precursors of one or more faults in the electric grid, one or more locations 104 where the one or more events 102 are detected, and one or more components 106 of the electric grid in which the one or more events are detected. The one or more components 106 include substations in the transmission network, substations in the distribution network, transmission lines in the transmission network, distribution lines in the distribution network, equipment in the transmission network, or equipment in the distribution network, and wherein the transmission lines and the distribution lines include one or more of lines, or cables of any type, whether overhead or underground.

The visual alert includes a map 110 of a real-world region, a risk index associated with each event of the one or more events 102 detected in the real-world region, and an urgency index associated with each event. The map 110 includes one or more pointers 113 and/or heat maps 112 indicative of one or more geolocations corresponding to the one or more locations 104, and a topology map of the electric grid 115. Each of the one or more pointers 113, or heatmaps, may further indicate a location of a corresponding sensor, e.g., traveling wave sensor, of a set of sensors. The visual alert 100 may be generated based on the one or more user inputs that include a time range 114, a time interval 116, and a frequency 118. The time range 114 includes a starting timestamp and an ending timestamp. The one or more events 102 are detected at the one or more geolocations within the time range 114. The time interval 116 is a day, a week, or a month, within the time range 114. The one or more events 102 are detected at the one or more geolocations within the time interval 116. The frequency 118 is continuous or sporadic. The one or more geolocations are determined based on detection of the one or more events within the time range, wherein the one or more events are continuous phenomena or sporadic phenomena.

The visual alert 100 further includes a histogram 120 or a time-graph that indicates a count of events and/or signal strength detected at each time-instance of a set of time-instances 122 within the time-range 114 or the time-interval 116, one or more characteristics associated with each event of the one or more events 102, a risk index, and/or an urgency index. The count of events and/or signal strength detected per a time-instance are shown as bars 130. A histogram 120 shows the count of events as a series of bars wherein bar's height indicates the count of events at a time-instance of question. The visual alert 100 further includes a list 124. Each entry of the list 124 may include a component of the one or more components 106 in which an event of the one or more events 102 is detected, a type 126 of the event, a time-instance 128 of occurrence of the event, and a geolocation at which the event is detected. The time-instance is within the time-range 114 or the time-interval 116.

FIG. 1 is merely an example, which should not unduly limit the scope of the claims herein. A person skilled in the art will recognize many variations, alternatives, and modifications of embodiments of the present disclosure.

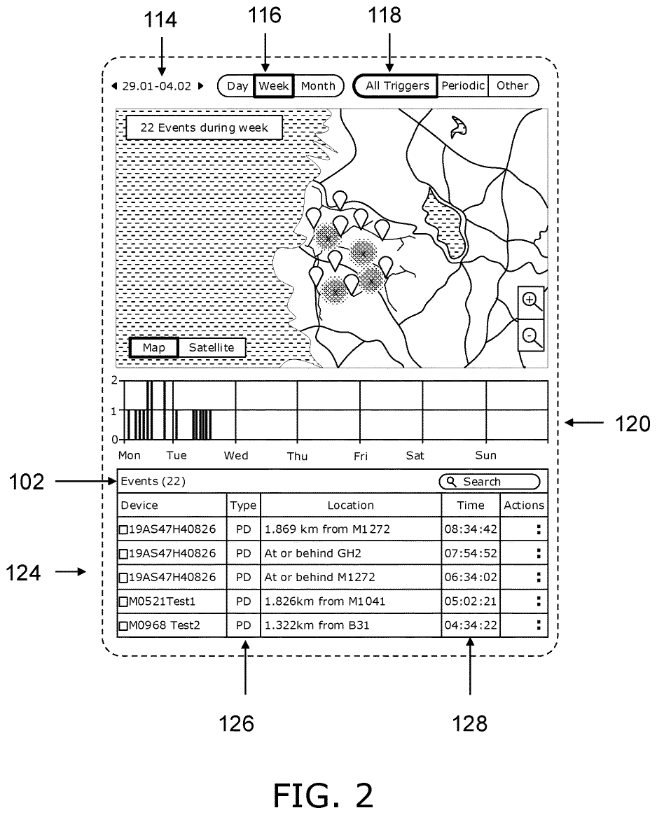

Referring to FIG. 2, there is illustrated an exemplary visual alert 200 that corresponds to prediction of faults in an electric grid, in accordance with an embodiment of the present disclosure. The visual alert 200 is generated based on the one or more inputs. The starting timestamp and the ending timestamp of time range 114 is “29^{th} January” and “4^{th} February” respectively. The time interval 116 is “Week” and the frequency 118 is “All triggers”. The histogram 120 or time-graph indicates a count of events or signal strength detected at each time-instance within “29^{th} January” and “4^{th} February”. The list 124 includes twenty-two entries corresponding to twenty-two events detected within “29^{th} January” and “4^{th} February”. Each entry may include a component (“Device”) of the one or more components 106 in which an event of the one or more events 102 is detected, a type 126 of the event, a time-instance 128 of occurrence of the event, and a location at which the event is detected.

FIG. 2 is merely an example, which should not unduly limit the scope of the claims herein. A person skilled in the art will recognize many variations, alternatives, and modifications of embodiments of the present disclosure.

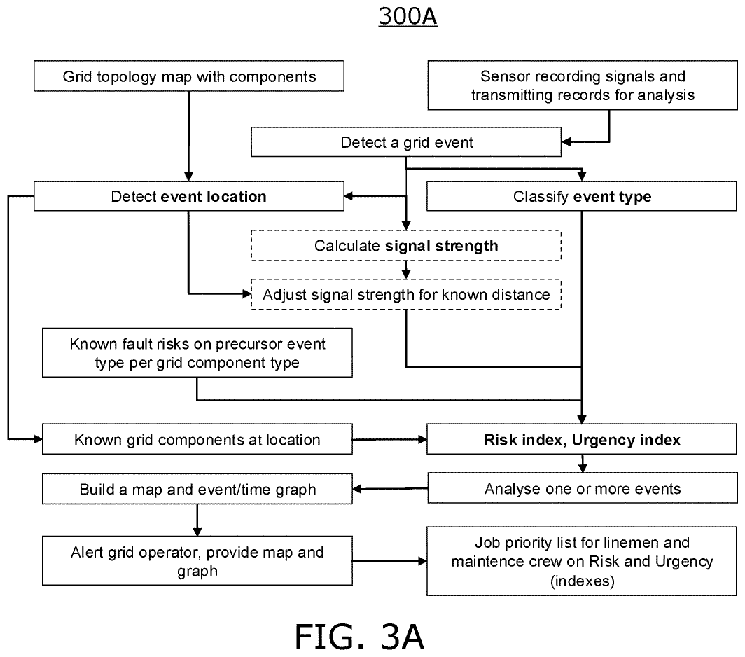

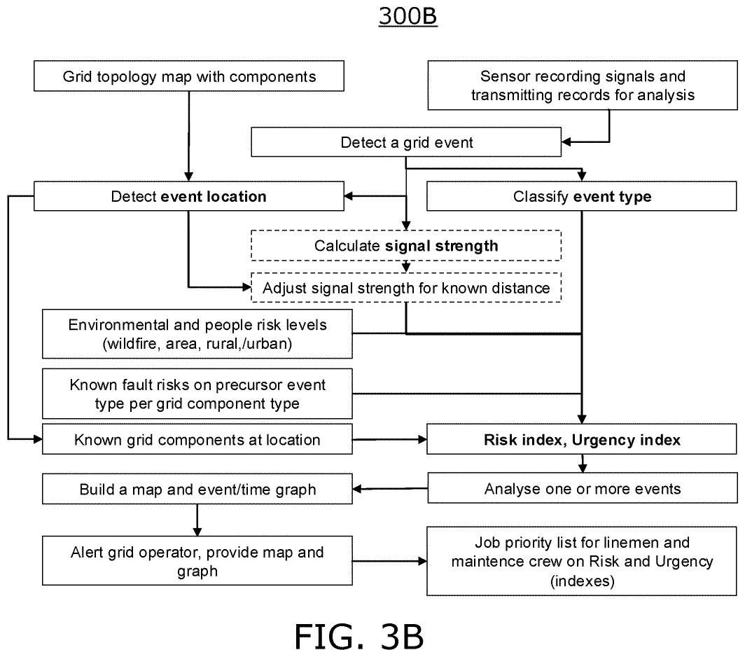

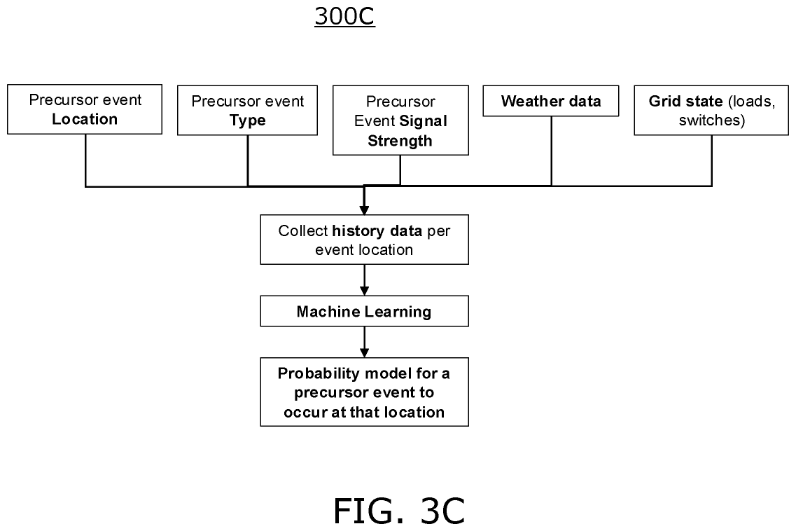

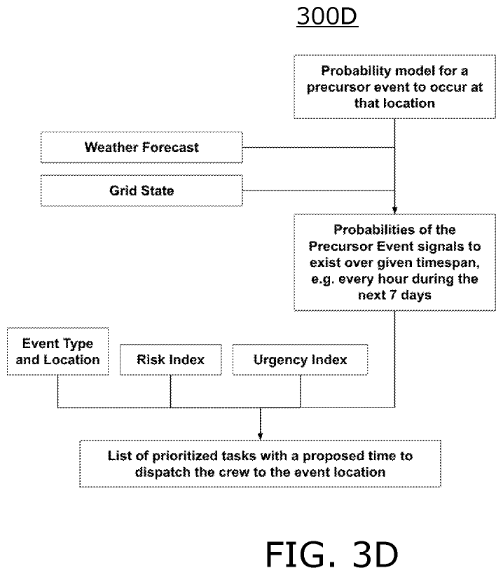

Referring to FIG. 3A, there is illustrated a flowchart 300A for prioritizing tasks for fixing issues in an electric grid, in accordance with an embodiment of the present disclosure. The fixing of the issues may prevent occurrence of a potential fault in the electric grid. The tasks may be prioritized based on a risk index and an urgency index. The risk index and an urgency index may be determined for each event of the one or more events that have been detected. In an embodiment, the risk index or the urgency index of an event is determined based on locations of (a set of) sensors that may be used for measuring parameters for detection of a location of the event, the location of the one or more locations where the event is detected, parameters (such as signal strength) of a signal associated with the event (which is propagating through the distribution network or the transmission network of the electric grid), a type to which the event is classified as, and association of the event as a precursor to a known fault occurring in a certain type of component in the electric grid.

Referring to FIG. 3B, there is illustrated a flowchart 300B for prioritizing tasks for fixing issues in an electric grid, in accordance with an embodiment of the present disclosure. The flowchart 300B differs from the flowchart 300A in that the flowchart 300B considers also environmental aspects and people risk levels, e.g., in wildfire areas, rural/urban areas.

For measuring the risk index, a model may be developed. The model combines features of the signals as an event type with historical fault data to estimate the risk level of each component or section of the electric grid. Machine learning models, statistical analysis, or expert systems may be used to correlate features of the signals with the likelihood of fault occurrence. For example, a risk score may be computed for each component by weighting features according to their predictive value for failure. For instance, a primary transformer with high temperature trends and frequent high-frequency disturbances is likely to be assigned with a higher risk score than a pole-mounted lightning arrester.

The purpose of the risk index is to describe the potential fatality if the component, which emits the precursor events and signals, would fail. By knowing the event location and possibly also the grid components at or near that location, and the trend of the emitted precursor events and signals, a risk index for a group of precursor events appearing in that location can be calculated. For example, a risk index can be in the range of 1 . . . 10 where 1 contributes low risk, and 10 very high risk. Then, if the location has an overhead line in a moist rural area without wildfire risks, and the precursor event type detected indicates a broken lightning arrestor with very small signal strength, the risk index could be very low, e.g. 2. However, for precursor events in a location which is known for wildfires and pole fires, and the area consists of urban or suburban areas, and the precursor event type indicates an insulator failure or a broken and downed conductor, the risk level can be very high, e.g., 8 for a broken insulator and 10 for a downed conductor (risk of electric shock). The urgency index, indicative of urgency of addressing a potential fault in a component, can be determined based on the trend of the Signal Strength of precursor events, together with event type, and known component(s) at that location. E.g., Low signal strengths of precursor event signals of an insulator may not be urgent to be repaired as typically the insulators fail gradually—the urgency index could be “Weeks”. As another example, a sparking blade switch component, due to bad contact, will soon cease to conduct at all, and probably will generate a considerable amount of heat. In this case the urgency index should be “Minutes”. A further example could be a lightning strike on an overhead line, which has been trapped by lightning arresters (overvoltage arresters). If there are very mild indicators of a damaged lightning arrester, the urgency index could be “Days”, as the probability of a slightly damaged lightning arrester to fail fatally soon is rather low. FIGS. 3A and 3B are merely examples, which should not unduly limit the scope of the claims herein. A person skilled in the art will recognize many variations, alternatives, and modifications of embodiments of the present disclosure.

Referring to FIG. 3C, there is illustrated a flowchart 300C for a probability model for a precursor event to occur at the location in an electric grid, in accordance with an embodiment of the present disclosure. In an embodiment a precursor event location, a precursor event type, a precursor event signal strength, weather data and a state of the electric grid, including e.g., but not limited to, states of loads, and states of switches, are collected to and stored as a history data per event location, and used in machine learning, which is used to provide a probability model for a precursor to occur at the location. Based on the provided probability model an event/events at a certain time-instance can be predicted.

FIG. 3D illustrates a flowchart for a list of prioritized tasks with a proposed time to dispatch the crew to the event location, in accordance with an embodiment of the present disclosure. The flowchart 300D in FIG. 3D is a continuation of the flow chart depicted in FIG. 3C. After the probability model for a precursor to occur at the location is provided the probabilities of the precursor event signals to exist over a given timespan, e.g., every hour during the next 7 days, are estimated by take into account the weather forecast and grid state. Further, by taken into account, the event type location, risk index, urgency index and said probabilities of the precursor event signals, a list of prioritized tasks with proposed time to dispatch the crew to event location is provided.

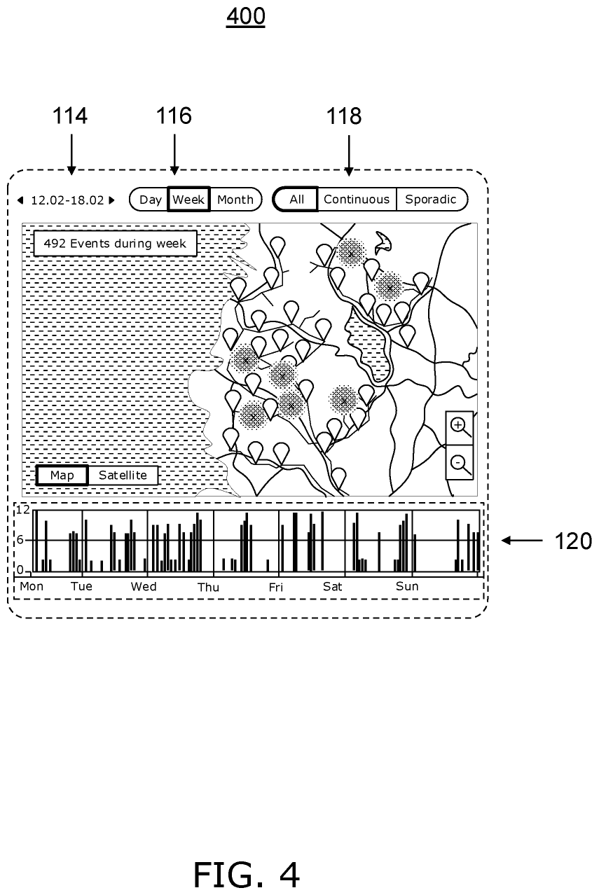

Referring to FIG. 4, there is illustrated an exemplary visual alert 400 that corresponds to prediction of faults in an electric grid, in accordance with an embodiment of the present disclosure. The starting timestamp and the ending timestamp of time range 114 is “12^{th} February” and “18^{th} February” respectively. The time interval 116 is “Week” (i.e., “Monday to Sunday”) and the frequency 118 is “All” (i.e., All triggers). The histogram 120 or time-graph indicates a count of events or signal strength detected at each time-instance within “12^{th} February” and “18^{th} February”. The list includes four hundred and ninety-two entries corresponding to four hundred and ninety-two events, shown on top of the map, detected within “12^{th} February” and “18^{th} February”. Each entry may include a component (“Device”) of the one or more components in which an event of the one or more events is detected, a type of the event, a time-instance of occurrence of the event, and a location at which the event is detected.

FIG. 4 is merely an example, which should not unduly limit the scope of the claims herein. A person skilled in the art will recognize many variations, alternatives, and modifications of embodiments of the present disclosure.

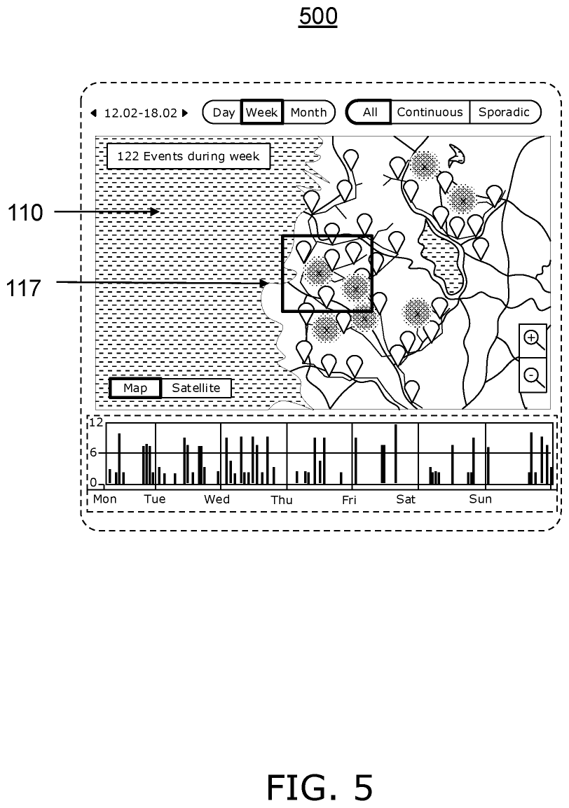

Referring to FIG. 5, there is illustrated an exemplary visual alert 500 that corresponds to prediction of faults in an electric grid, in accordance with an embodiment of the present disclosure. The visual alert 500 is generated based on an input. The input may be a selection of an area 117 (shown inside a rectangle in FIG. 5) on the map 110 of the visual alert 500. Based on the selection, events detected within the area may be rendered on the map 110. The time-graph further indicates events detected at each time-instance of a set of time-instances within the selected area. The list includes one hundred and twenty-two entries, shown on top of the map, corresponding to one hundred and twenty-two detected in the selected area.

FIG. 5 is merely an example, which should not unduly limit the scope of the claims herein. A person skilled in the art will recognize many variations, alternatives, and modifications of embodiments of the present disclosure.

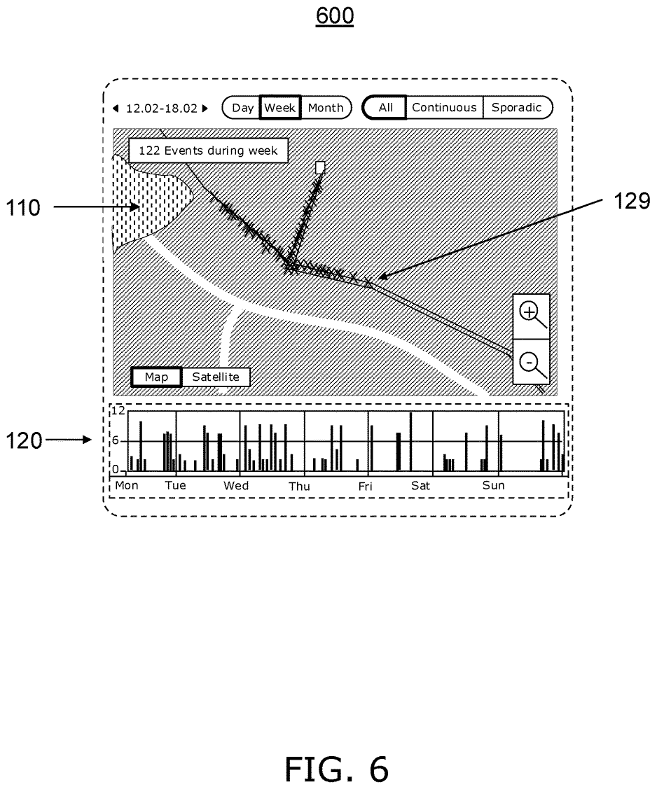

Referring to FIG. 6, there is illustrated an exemplary visual alert 600 that corresponds to prediction of faults in an electric grid, in accordance with an embodiment of the present disclosure. The visual alert 600 is generated based on an input. The input may be a zoom gesture (e.g., by a user) on one of the events detected within the area. Based on reception of the zoom gesture, details associated with the specific event may be rendered on the map 110. FIG. 6 shows the area selected in FIG. 5 enlarged, showing the selected area in more detail, and the detected events, at their locations, on the power line of the electric grid, wherein the events marked with “X” 129. The time-graph 120 further indicates events detected at each time-instance of a set of time-instances within the selected area.

FIG. 6 is merely an example, which should not unduly limit the scope of the claims herein. A person skilled in the art will recognize many variations, alternatives, and modifications of embodiments of the present disclosure.

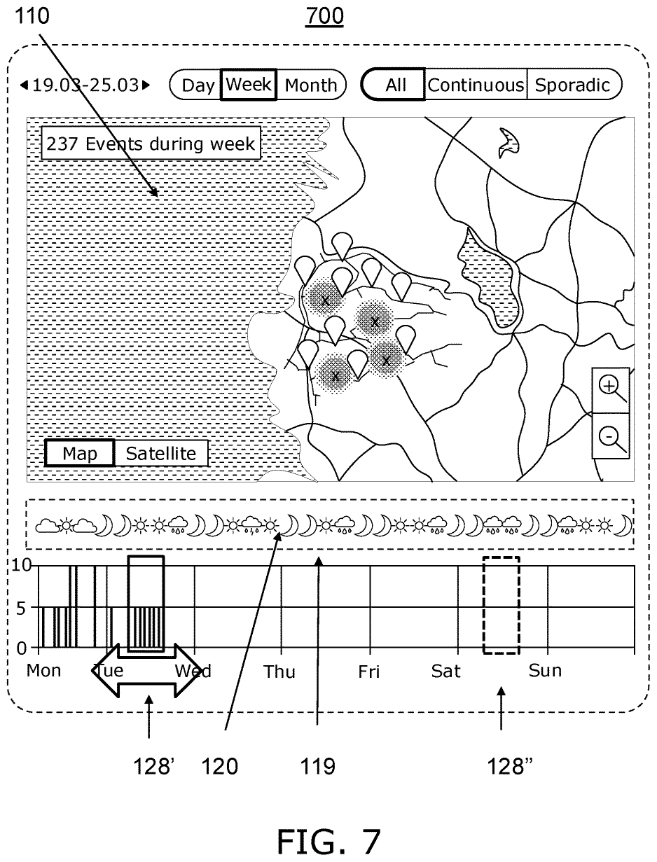

Referring to FIG. 7, there is illustrated an exemplary visual alert 700 that corresponds to prediction of faults in an electric grid, in accordance with an embodiment of the present disclosure. The map 110 in the visual alert 700 includes weather data 119 at, or in vicinity of, the one or more geolocations corresponding to the one or more locations where the one or more events (a total of 237 events during week) are detected. The histogram, or time-graph, 120 includes the weather data 119 at the one or more locations during each time-instance 128 of the set of time-instances. The weather data includes one or more of temperature, humidity, wind speed, lightning condition, and a thunderstorm condition. Based on selection of the area, where the events have been detected, weather conditions at the area may be rendered. In FIG. 7, the selection of time-instance 128′ in the time-graph 120 is represented by a double-pointed arrow. By moving the selection, or selection bar (two-way arrow in the FIG. 7) to the right or left, the user can select the desired time-instance for further evaluation. The rectangle 128″, which is represented by dashed lines on top of the time-graph, depicts the predictive machine learning model's prediction of events at a certain time-instance. The benefit of the above-mentioned event occurrence prediction based on load and weather conditions is that the maintenance crew can be sent out for investigations at a time when there is the highest probability of the failing component to emit the precursor signal.

FIG. 7 is merely an example, which should not unduly limit the scope of the claims herein. A person skilled in the art will recognize many variations, alternatives, and modifications of embodiments of the present disclosure.

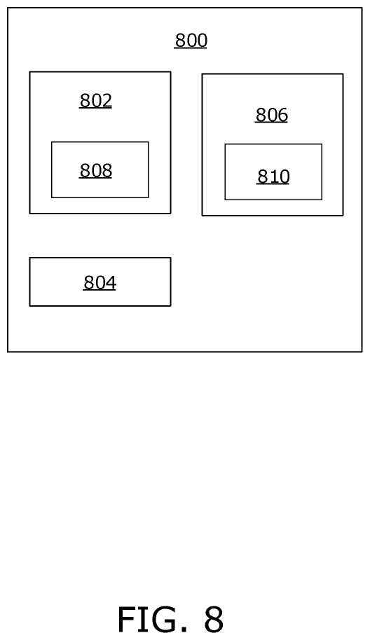

Referring to FIG. 8, there is shown a schematic diagram of a system 800 for predicting faults in electric grids, in accordance with an embodiment of the present disclosure. The system 800 comprises a server 802, a set of sensors 804, and a user device 806. The server 802 includes a processor 808. The user device 806 includes a display device 810. The processor 808 may collect measurements from the set of sensors 804. The set of sensors 804 may include a magnetic field detection sensor, an electric field detection sensor, an electromagnetic field detection sensor, an accelerometer, a temperature sensor, a wind detection sensor, a lightning sensor, a humidity sensor, a strain gauge sensor, a vibration sensor, an image sensor, a motion sensor, or a personal digital device, an acoustic sensor, an ultrasound sensor, an infrared sensor, an ultraviolet sensor, or a traveling wave sensor. The processor 808 receives signals that are propagating through a distribution network or a transmission network of an electric grid. In an event, the reception may be triggered periodically, or the reception may be triggered based on reception of a user input that includes an instruction to fetch events that may occurred in the electric grid in a particular location over a certain time range or period.

The processor 808 is capable of detecting one or more events that are precursors of one or more faults in the electric grid. The detection is based on at least one of parameters associated with the received signals or radiation produced by operation of components in the distribution network or the transmission network. Said events are detected by use of the set of sensors 804. The processor 808 determines one or more locations, in the distribution network or the transmission network, where the one or more events are detected, wherein the determination is based on one or more of: a pattern of detection of the one or more events, weather conditions, traveling wave analysis, or location-specific sensor measurements. Based on detection, the processor 808 generates an alert (alerts) that includes the one or more events, the one or more locations, and one or more components of the electric grid in which the one or more events are detected, wherein the alert corresponds to predictions of occurrences of the one or more faults.

It may be understood by a person skilled in the art that FIG. 8 includes a simplified architecture of the system 800, for sake of clarity, which should not unduly limit the scope of the claims herein. It is to be understood that the specific implementation of the system 800 is provided as an example and is not to be construed as limiting. The person skilled in the art will recognize variations, alternatives, and modifications of embodiments of the present disclosure.

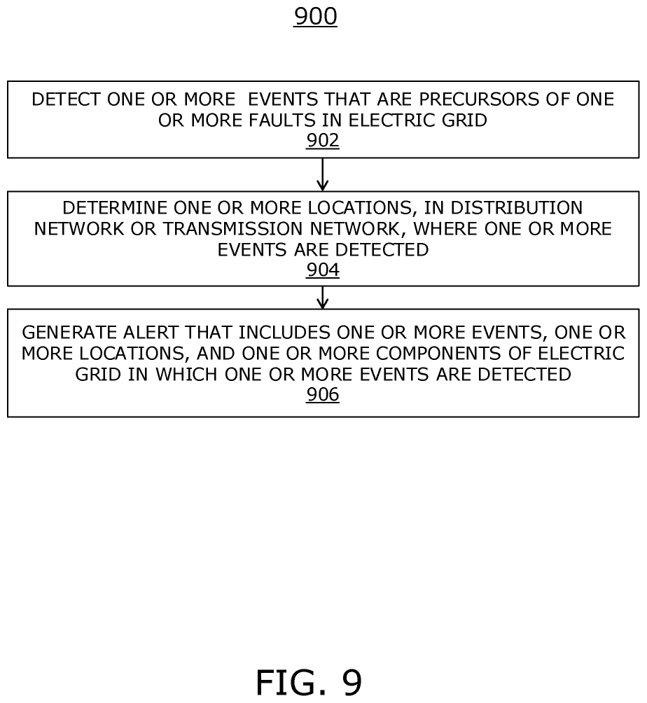

FIG. 9 illustrates steps of a method for detecting one or more events, determining one or more locations, and generating alerts that include one or more events, one or more locations, and one or more components of the electric grid, in accordance with an embodiment of the present disclosure. At step 902, one or more events 102, that are precursors of one or more faults in the electric grid, are detected. The detection is based on at least one of parameters associated with signals propagating through a distribution network or a transmission network of the electric grid or radiation produced by operation of components in the distribution network or the transmission network. At step 904, one or more locations 104, in the distribution network or the transmission network, where the one or more events are detected, may be determined. The determination is based on one or more of: a pattern of detection of the one or more events, weather conditions, traveling wave analysis, or location-specific sensor measurements. At step 906, an alert 100 that includes the one or more events, the one or more locations, and one or more components 106 of the electric grid, in which the one or more events are detected, are generated. The alert corresponds to predictions of occurrences of the one or more faults.

The aforementioned steps are only illustrative and other alternatives can also be provided where one or more steps are added, one or more steps are removed, or one or more steps are provided in a different sequence without departing from the scope of the claims herein.

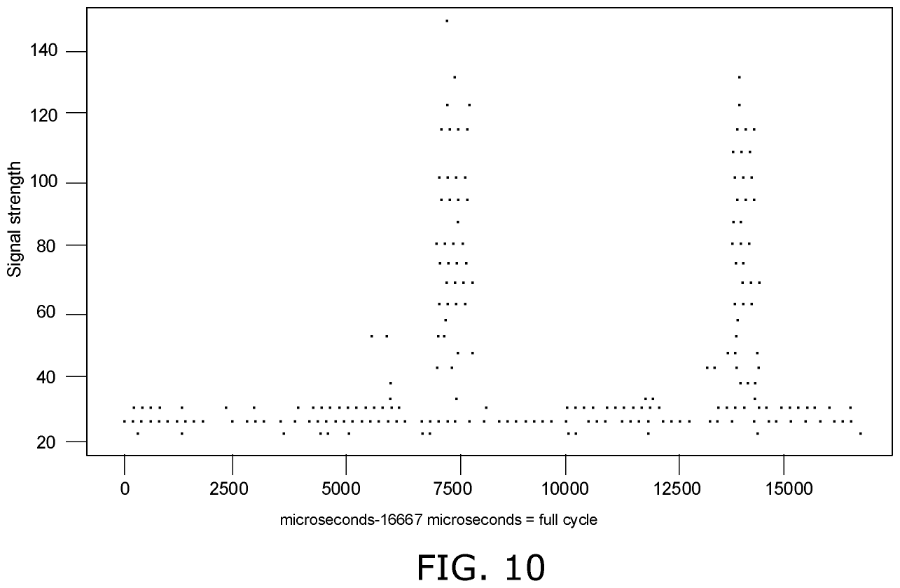

FIG. 10 shows a phase resolved partial discharge view, in accordance with an embodiment of the present disclosure. The phase resolved partial discharge view of FIG. 10 is depicted, when zooming into the map 110 or when clicking on the graph 120, e.g., the bar 130 on the time-graph. When zooming or clicking, the individual event locations are then displayed on the map as icons 113 or markers 112 and on histogram or time-graph 120 as icons or markers 130 (shown in FIG. 6) at that time, and the user can further click or touch on the icon or marker to open detailed view of this event, and a phase-resolved partial discharge (PRPD) diagram of the partial discharge or phase synchronous signal of the sensors detecting the event.

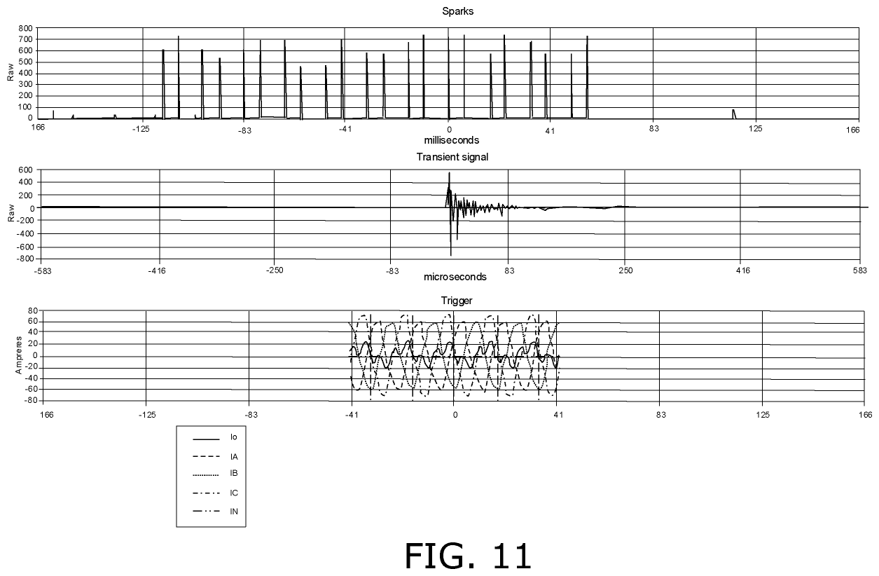

FIG. 11 shows oscillographs of the high frequency and phase signals, in accordance with an embodiment of the present disclosure. The oscillographs view of FIG. 11 is depicted when zooming into the map 110 or graph 120, the individual event locations are displayed on the map as icons 113 or markers 112 and on graph 120 as icons or markers 129 at that time, and the user can click or touch on the icon or marker to open up detailed view of this event, including the signal data amplitude vs time of the sensors detecting that event.

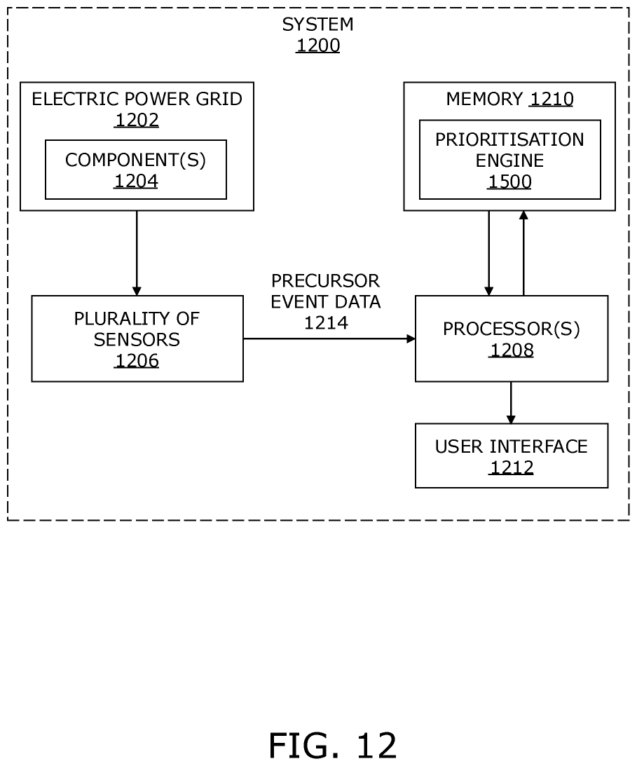

Referring to FIG. 12, illustrated is a schematic block diagram of a system 1200 for prioritizing maintenance actions in an electric power grid 1202, in accordance with a further embodiment of the present disclosure. The system 1200 comprises one or more processors 1208, a memory 1210, and a user interface 1212. The memory 1210 is communicatively coupled to the one or more processors 1208 and stores instructions that, when executed by the one or more processors 1208, cause the system 1200 to perform the operations described herein. The memory 1210 further comprises a prioritization engine 1500, in the form of a module, that is configured to compute the plurality of independent priority dimensions and to generate the composite priority score. The electric power grid 1202 comprises a plurality of components 1204 including conductors, cables, cable joints, cable terminations, overhead line segments, switchgear, transformers, and other electrical equipment. A plurality of sensors 1206 is deployed in the electric power grid 1202 and is communicatively coupled to the one or more processors 1208. The plurality of sensors 1206 is configured to detect one or more precursor events occurring at the plurality of components 1204 and to transmit precursor event data 1214 to the one or more processors 1208. The one or more processors 1208 receive the precursor event data 1214 from the plurality of sensors 1206, process the precursor event data 1214 using the prioritization engine 1500 stored in the memory 1210, and generate the ranked list that is rendered on the user interface 1212. The user interface 1212 is communicatively coupled to the one or more processors 1208 and is configured to display the ranked list, the topology map of the electric power grid 1202, and the priority state indicators for the plurality of locations.

The system 1200, as described in the preceding paragraph, receives the precursor event data 1214 that is generated by detection and localization of one or more precursor events performed in accordance with the detection networks and arrangements described in the foregoing passages, including the system 800 illustrated in FIG. 8 and the set of sensors 804 illustrated in FIG. 8. The system 1200 operates as a prioritization and maintenance management layer that processes the precursor event data 1214 generated by the system 800 and the set of sensors 804 to compute the plurality of independent priority dimensions, to generate the composite priority score, and to generate the ranked list for prioritizing the maintenance actions in the electric power grid 1202. The system 1200 does not replace the system 800; rather, the system 1200 receives outputs of the system 800 as inputs and provides automated decision support based on the precursor event data 1214 so received. The plurality of sensors 1206 depicted in FIG. 12 may correspond to the set of sensors 804 depicted in FIG. 8, and the one or more processors 1208 depicted in FIG. 12 may be implemented within the server 802 depicted in FIG. 8 or as a separate processing unit communicatively coupled to the server 802.

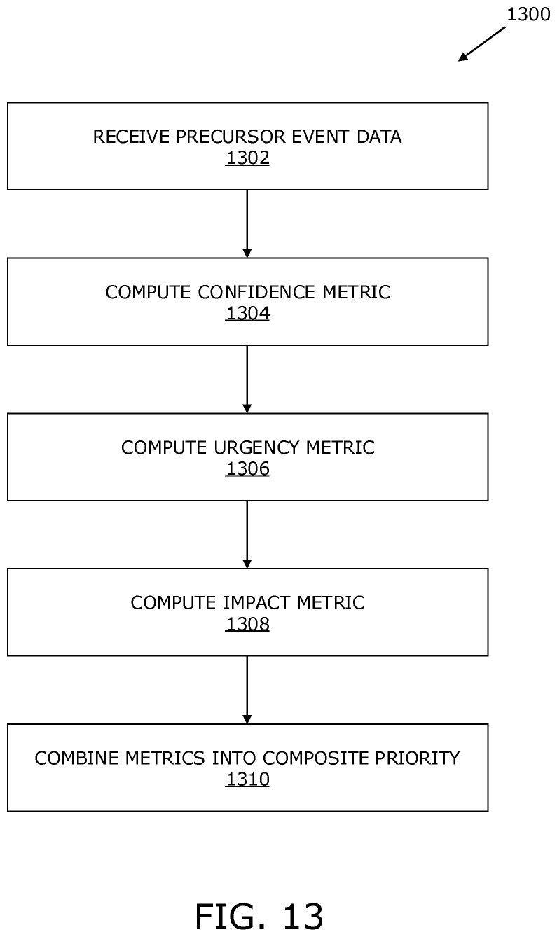

Referring to FIG. 13, illustrated is a flowchart of a computer-implemented method 1300 for prioritizing maintenance actions in the electric power grid 1202, in accordance with a further embodiment of the present disclosure. The method 1300 begins at step 1302 in which the system 1200 receives the precursor event data 1214 associated with the plurality of locations in the electric power grid 1202. At step 1304, the system 1200 computes, for each location of the plurality of locations, the plurality of independent priority dimensions based on the precursor event data 1214. The plurality of independent priority dimensions comprises the confidence metric, the urgency metric, and the impact metric as described herein. At step 1306, the system 1200 combines the confidence metric, the urgency metric, and the impact metric to generate the composite priority score for each location of the plurality of locations. At step 1308, the system 1200 generates the ranked list of the plurality of locations based on the composite priority score. At step 1310, the system 1200 outputs the ranked list for prioritizing the maintenance actions in the electric power grid 1202.

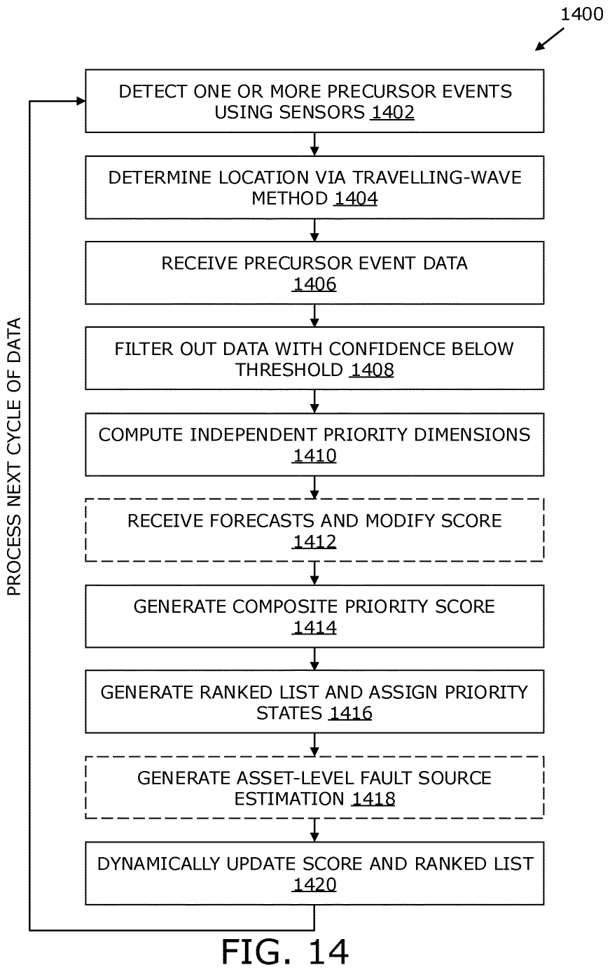

Referring to FIG. 14, illustrated is a detailed flowchart of a method 1400 including detection, travelling-wave localization, and dynamic updating for prioritizing maintenance actions in the electric power grid 1202, in accordance with a further embodiment of the present disclosure. The method 1400 begins at step 1402 in which the system 1200 detects one or more precursor events using the plurality of sensors 1206. At step 1404, the system 1200 determines the location for each detected precursor event using the travelling-wave method based on differences in arrival times of travelling waves received at the plurality of sensors 1206. Optionally, at step 1404, the system 1200 further analyses one or more of a propagation time, an attenuation, a polarity, and reflected waves to refine the location determination. At step 1406, the system 1200 receives the precursor event data 1214 generated from the detection and localization performed at steps 1402 and 1404. At step 1408, the system 1200 filters out the precursor event data 1214 having the confidence metric below the threshold. At step 1410, the system 1200 computes the plurality of independent priority dimensions, including the confidence metric, the urgency metric, and the impact metric, for each location of the plurality of locations that remains after the filtering. Optionally, at step 1412, the system 1200 receives the forecast of ambient conditions and the forecast of load conditions and modifies the composite priority score based on the received forecasts. At step 1414, the system 1200 combines the confidence metric, the urgency metric, and the impact metric to generate the composite priority score. At step 1416, the system 1200 generates the ranked list and assigns each location to one of the plurality of priority states. Optionally, at step 1418, the system 1200 generates the asset-level fault source estimation by inferring the failing component type for at least one location based on the precursor event data 1214 and historical pattern recognition. At step 1420, the system 1200 dynamically updates the composite priority score and the ranked list based on a continuous reception of new precursor event data 1214, and the method 1400 returns to step 1402 to process the next cycle of precursor event data.

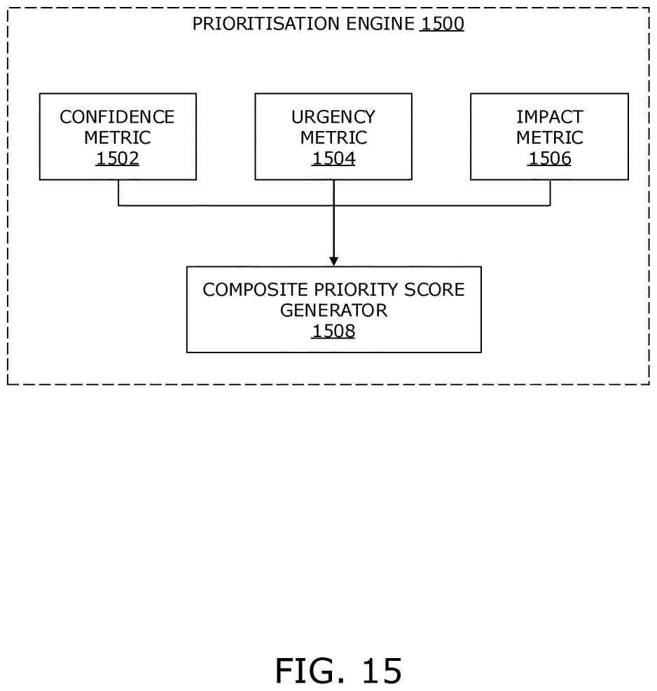

Referring to FIG. 15, illustrated is a block diagram of an architecture of a prioritization engine 1500 for computing the plurality of independent priority dimensions and generating the composite priority score, in accordance with a further embodiment of the present disclosure. The prioritization engine 1500 receives inputs including the precursor event data, data defining the topology of the electric power grid, and optionally the forecast of ambient conditions and the forecast of load conditions. The prioritization engine 1500 comprises a confidence metric computation module 1502, an urgency metric computation module 1504, and an impact metric computation module 1506. The confidence metric computation module 1502 receives the precursor event data 1214 and computes the confidence metric based on signal quality and statistical distribution characteristics of the precursor event data 1214 at each location of the plurality of locations. The urgency metric computation module 1504 receives the precursor event data 1214 and computes the urgency metric based on the rate of change of the event frequency and the energy trajectory of the precursor event activity at each location. The impact metric computation module 1506 receives data defining the topology of the electric power grid 1202 and computes the impact metric based on the topology of the electric power grid 1202 and the estimated loss of electrical load associated with each location. The prioritization engine 1500 further comprises a composite priority score generator 1508 that receives the outputs of the confidence metric computation module 1502, the urgency metric computation module 1504, and the impact metric computation module 1506 and combines the confidence metric, the urgency metric, and the impact metric to generate the composite priority score for each location. The composite priority score generator 1508 outputs the composite priority scores that are used to generate the ranked list.

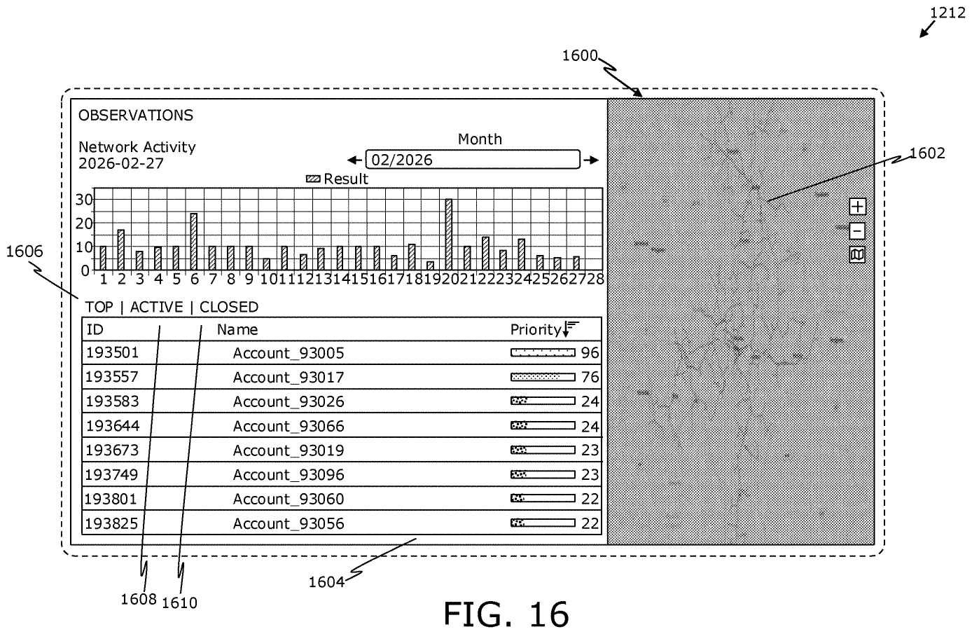

Referring to FIG. 16, illustrated is a map view 1600 of the user interface 1212 rendering a ranked list 1604 of the plurality of locations on a topology map 1602 of the electric power grid 1202, in accordance with a further embodiment of the present disclosure. The topology map 1602 shows the spatial layout of the electric power grid 1202 including feeders, branches, and interconnection points. The ranked list 1604 is displayed alongside the topology map 1602 and lists the plurality of locations ordered by the composite priority score. Each location in the ranked list 1604 is assigned to one of the plurality of priority states. A top state indicator 1606 identifies locations assigned to the top state, indicating the highest priority requiring prompt attention. An active state indicator 1608 identifies locations assigned to the active state, indicating ongoing precursor event activity warranting monitoring. A closed state indicator 1610 identifies locations assigned to the closed state, indicating that precursor event activity has subsided or been resolved. The topology map 1602 displays visual markers at the corresponding locations in the electric power grid 1202, with the visual markers using color codes or other visual indicators corresponding to the assigned priority state. The map view 1600 enables operators to see the spatial relationship between the prioritized locations and the network topology, including downstream load branches connected through each location.

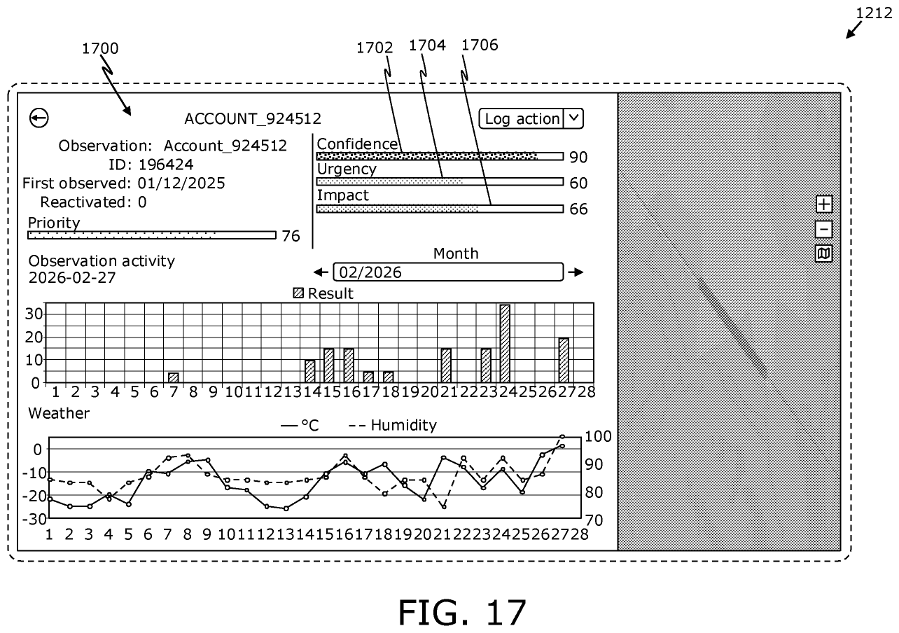

Referring to FIG. 17, illustrated is an event view 1700 of the user interface 1212 illustrating an event cluster on a single feeder, in accordance with a further embodiment of the present disclosure. The event view 1700 displays detailed information about the precursor event activity at a selected location. The event view 1700 comprises a visual representation of the confidence metric 1702, a visual representation of the urgency metric 1704, and a visual representation of the impact metric 1706 for the selected location. The visual representation of the confidence metric 1702 presents the computed value of the confidence metric for the selected location. The visual representation of the urgency metric 1704 presents the computed value of the urgency metric for the selected location. The visual representation of the impact metric 1706 presents the computed value of the impact metric for the selected location. The event view 1700 further presents the composite priority score for the selected location and a temporal chart showing the observation activity of precursor events at the selected location over time. The event view 1700 further presents a spatial view showing the position of the event cluster within the feeder on the topology map 1602. The event view 1700 enables operators to examine the individual dimensions of the priority assessment for a selected location and to understand the contribution of each of the confidence metric, the urgency metric, and the impact metric to the composite priority score.

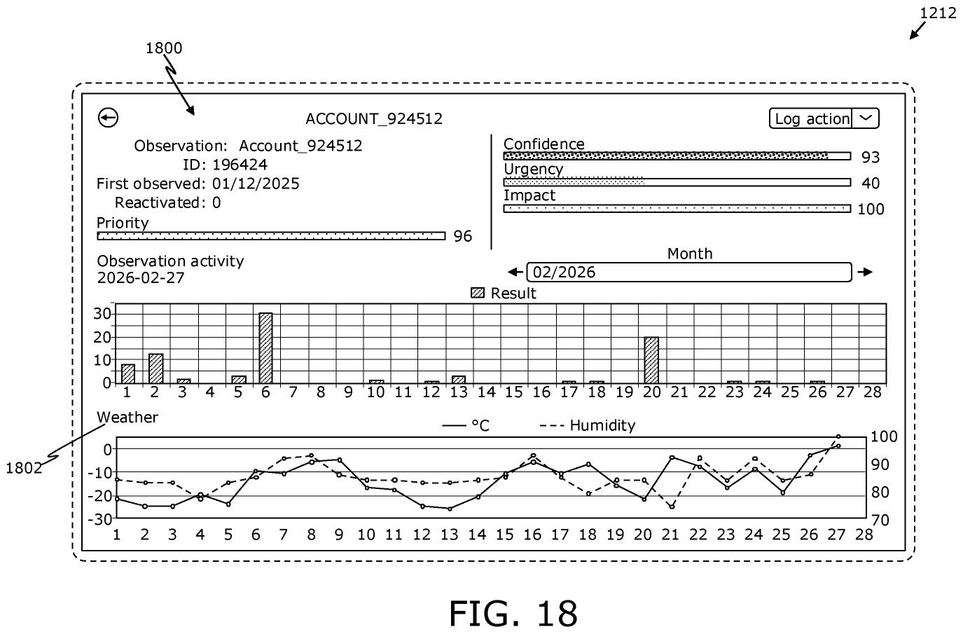

Referring to FIG. 18, illustrated is an event detail view 1800 of the user interface 1212 illustrating correlation of an event cluster with a forecast of ambient conditions 1802, in accordance with a further embodiment of the present disclosure. The event detail view 1800 displays the precursor event activity at a selected location alongside the forecast of ambient conditions 1802 for the same time period. The forecast of ambient conditions 1802 includes temperature data, humidity data, and other environmental parameters. The event detail view 1800 presents a temporal chart of the observation activity of precursor events at the selected location overlaid with or displayed adjacent to a temporal chart of the forecast of ambient conditions 1802. The event detail view 1800 enables operators to visually correlate changes in precursor event activity with changes in ambient conditions, such as temperature variations and humidity fluctuations. The event detail view 1800 further displays the confidence metric, the urgency metric, and the impact metric for the selected location. The correlation of the precursor event activity with the forecast of ambient conditions 1802 supports the forecast-based modification of the composite priority score as described herein.

Further, the oscillographs depicted in FIG. 11 illustrate the type of precursor event data 1214 that is detected by the plurality of sensors 1206 and that serves as input to the computation of the plurality of independent priority dimensions by the prioritization engine 1500. The oscillographs depicted in FIG. 11 further illustrate that early-stage, low-energy partial discharge events can be captured by sensors operating at high sampling rates, including sampling rates exceeding one megahertz, and that the captured signal data includes information about the amplitude, duration, and energy of the partial discharge event. The high-frequency signal waveform depicted in FIG. 11 exhibits a fast-rise-time pulse that is characteristic of partial discharge events, and the phase signal waveform depicted in FIG. 11 shows the relationship of the partial discharge event to the phase of the alternating current in the electric power grid 1202.

It may be noted that FIGS. 1 through 18 illustrate merely examples, which should not unduly limit the scope of the claims herein. A person skilled in the art will recognize many variations, alternatives, and modifications of embodiments of the present disclosure.

1. A computer-implemented method for prioritizing maintenance actions in an electric power grid, the method comprising:
receiving precursor event data associated with a plurality of locations in the electric power grid;
computing, for each location of the plurality of locations, a plurality of independent priority dimensions based on the precursor event data, the plurality of independent priority dimensions comprising:
(a) a confidence metric indicative of a reliability of the precursor event data at the location, wherein the confidence metric is computed based on signal quality and statistical distribution characteristics of the precursor event data;
(b) an urgency metric indicative of a temporal development of precursor event activity at the location, wherein the urgency metric is computed based on a rate of change of an event frequency of the precursor event activity and an energy trajectory of the precursor event activity; and
(c) an impact metric indicative of a consequence of a fault at the location, wherein the impact metric is determined based on a topology of the electric power grid and an estimated loss of electrical load associated with the location;
combining the confidence metric, the urgency metric, and the impact metric to generate a composite priority score for each location of the plurality of locations; and
generating a ranked list of the plurality of locations based on the composite priority score for prioritizing the maintenance actions in the electric power grid.

2. The method according to claim 1, further comprising:
detecting one or more precursor events using a plurality of sensors to generate the precursor event data; and
determining the location for each precursor event of the one or more precursor events using a travelling-wave method.

3. The method according to claim 2, wherein the travelling-wave method comprises determining the location for each precursor event of the one or more precursor events based on differences in arrival times of travelling waves received at the plurality of sensors.

4. The method according to claim 1, wherein the travelling-wave method further comprises analyzing one or more of a propagation time, an attenuation, a polarity, and reflected waves to refine the location for each precursor event of the one or more precursor events.

5. The method according to claim 1, wherein the precursor event data is associated with a partial discharge event or a high-impedance fault event.

6. The method according to claim 1, further comprising filtering out the precursor event data having the confidence metric below a threshold prior to generating the ranked list of the plurality of locations.

7. The method according to claim 1, wherein generating the ranked list of the plurality of locations comprises assigning each location of the plurality of locations to one of a plurality of priority states, the plurality of priority states comprising a top state, an active state, and a closed state.

8. The method according to claim 1, further comprising:
receiving a forecast of ambient conditions and a forecast of load conditions for a future time period; and
modifying the composite priority score based on the forecast of ambient conditions and the forecast of load conditions.

9. The method according to claim 1, further comprising:
generating a user interface comprising a topology map of the electric power grid; and
rendering the ranked list of the plurality of locations on the topology map.

10. The method according to claim 1, further comprising generating a maintenance recommendation for at least one location of the ranked list of the plurality of locations, wherein the maintenance recommendation comprises one or more of an inspection instruction, a monitoring instruction, a scheduling of a planned outage, and a dispatch of a maintenance crew.

11. The method according to claim 1, further comprising generating an asset-level fault source estimation by inferring a failing component type for at least one location of the plurality of locations based on the precursor event data and historical pattern recognition.

12. The method according to claim 1, further comprising dynamically updating the composite priority score and the ranked list of the plurality of locations based on a continuous reception of new precursor event data.

13. A system for prioritizing maintenance actions in an electric power grid, the system comprising:
one or more processors; and
a memory storing instructions that, when executed by the one or more processors, cause the system to:
receive precursor event data associated with a plurality of locations in the electric power grid;
compute, for each location of the plurality of locations, a plurality of independent priority dimensions based on the precursor event data, the plurality of independent priority dimensions comprising:
(a) a confidence metric indicative of a reliability of the precursor event data at the location, wherein the confidence metric is computed based on signal quality and statistical distribution characteristics of the precursor event data;
(b) an urgency metric indicative of a temporal development of precursor event activity at the location, wherein the urgency metric is computed based on a rate of change of an event frequency of the precursor event activity and an energy trajectory of the precursor event activity; and
(c) an impact metric indicative of a consequence of a fault at the location, wherein the impact metric is determined based on a topology of the electric power grid and an estimated loss of electrical load associated with the location;
combine the confidence metric, the urgency metric, and the impact metric to generate a composite priority score for each location of the plurality of locations; and
generate a ranked list of the plurality of locations based on the composite priority score for prioritizing the maintenance actions in the electric power grid.

14. The system according to claim 13, wherein the instructions further cause the system to:
detect one or more precursor events using a plurality of sensors to generate the precursor event data; and
determine the location for each precursor event of the one or more precursor events using a travelling-wave method based on differences in arrival times of travelling waves received at the plurality of sensors.

15. The system according to claim 13, wherein the instructions further cause the system to filter out the precursor event data having the confidence metric below a threshold prior to generating the ranked list of the plurality of locations.

16. The system according to claim 13, wherein the instructions further cause the system to assign each location of the plurality of locations to one of a plurality of priority states, the plurality of priority states comprising a top state, an active state, and a closed state.

17. The system according to claim 13, wherein the instructions further cause the system to:
receive a forecast of ambient conditions and a forecast of load conditions for a future time period; and
modify the composite priority score based on the forecast of ambient conditions and the forecast of load conditions.

18. The system according to claim 13, wherein the instructions further cause the system to:
generate a user interface comprising a topology map of the electric power grid; and
render the ranked list of the plurality of locations on the topology map.

19. The system according to claim 13, wherein the instructions further cause the system to generate a maintenance recommendation for at least one location of the ranked list of the plurality of locations, wherein the maintenance recommendation comprises one or more of an inspection instruction, a monitoring instruction, a scheduling of a planned outage, and a dispatch of a maintenance crew.

20. The system according to claim 13, wherein the instructions further cause the system to dynamically update the composite priority score and the ranked list of the plurality of locations based on a continuous reception of new precursor event data.

21. A computer-implemented method for prioritizing maintenance actions in an electric power grid, the method comprising:
detecting one or more precursor events using a plurality of sensors to generate precursor event data;
determining, for each precursor event of the one or more precursor events, a location using a travelling-wave method based on differences in arrival times of travelling waves received at the plurality of sensors, such that the precursor event data is associated with a plurality of locations in the electric power grid;
computing, for each location of the plurality of locations, a plurality of independent priority dimensions based on the precursor event data, the plurality of independent priority dimensions comprising:
(a) a confidence metric indicative of a reliability of the precursor event data at the location, wherein the confidence metric is computed based on signal quality and statistical distribution characteristics of the precursor event data;
(b) an urgency metric indicative of a temporal development of precursor event activity at the location, wherein the urgency metric is computed based on a rate of change of an event frequency of the precursor event activity and an energy trajectory of the precursor event activity; and
(c) an impact metric indicative of a consequence of a fault at the location, wherein the impact metric is determined based on a topology of the electric power grid and an estimated loss of electrical load associated with the location;
combining the confidence metric, the urgency metric, and the impact metric to generate a composite priority score for each location of the plurality of locations; and
generating a ranked list of the plurality of locations based on the composite priority score for prioritizing the maintenance actions in the electric power grid.

22. The method according to claim 21, wherein the travelling-wave method further comprises analyzing one or more of a propagation time, an attenuation, a polarity, and reflected waves to refine the location for each precursor event of the one or more precursor events.

23. The method according to claim 21, further comprising filtering out the precursor event data having the confidence metric below a threshold prior to generating the ranked list of the plurality of locations.

24. The method according to claim 21, further comprising dynamically updating the composite priority score and the ranked list of the plurality of locations based on a continuous reception of new precursor event data.

25. The method according to claim 21, wherein generating the ranked list of the plurality of locations comprises assigning each location of the plurality of locations to one of a plurality of priority states, the plurality of priority states comprising a top state, an active state, and a closed state.

26. A computer-implemented method for prioritising maintenance actions in an electric power grid, the method comprising:
finding locations of one or more grid fault sources or signal sources in the electric power grid using arrival time analysis of signals originating from or caused by said signal sources, the signals being recorded by a plurality of data-network-connected sensors monitoring grid conductors and components at geographically distributed locations along grid circuits and branches;
receiving precursor event data associated with the plurality of locations in the electric power grid;
computing, for each location of the plurality of locations, a plurality of independent priority dimensions based on the precursor event data, the plurality of independent priority dimensions comprising:
(a) a confidence metric indicative of a reliability of the precursor event data at the location, wherein the confidence metric is computed based on signal characteristics of the precursor event data;
(b) an urgency metric indicative of a temporal development of precursor signal activity at the location, wherein the urgency metric is computed based on a rate of change of signal activity emitted from the location, the signal activity being identified as originating from that location using analysis of signal arrival times; and
(c) an impact metric indicative of a consequence of a fault at the location, wherein the impact metric is determined based on a topology of the electric power grid and an estimated loss of electrical load or number of users associated with the location;
combining the confidence metric, the urgency metric, and the impact metric to generate a composite priority score for each location of the plurality of locations; and
generating a ranked list of the plurality of locations based on the composite priority score for prioritising the maintenance actions in the electric power grid.
